(19) United States
(12) Patent Application Publication
(10) Pub. No.: US 2024/0206231 A1
(43) Pub. Date: Jun. 20, 2024

(54) Display Device and Display Panel

(71) Applicant: LG Display Co., Ltd., Seoul (KR)

(72) Inventors: Youngsung Cho, Paju-si (KR); Byeong-Seong So, Seoul (KR)

(21) Appl. No.: 18/528,466

(22) Filed: Dec. 4, 2023

(30) Foreign Application Priority Data
Dec. 14, 2022 (KR) 10-2022-0174345

(51) Int. Cl. H10K 59/121; H10K 59/131

(52) U.S. Cl. CPC H10K 59/1213; H10K 59/131

(57) ABSTRACT

A display device and a display panel are disclosed that include an efficient arrangement of pixel circuits of a first optical bezel area due to the display panel requiring a high resolution or low power consumption. The first optical bezel area is positioned between a first optical area and the normal area. A plurality of first subpixel circuit units and a plurality of second subpixel circuit units are disposed in the first optical bezel area, and a plurality of third subpixel circuit units are disposed in the normal area. At least one of a length in a first direction and a length in a second direction of the first and second subpixel circuit units is different from the length in the first direction and the length in the second direction of the third subpixel circuit unit.

### CROSS-REFERENCE TO RELATED APPLICATION

This application claims priority from Republic of Korea Patent Application No. 10-2022-0174345, filed on Dec. 14, 2022, which is hereby incorporated by reference in its entirety.

### BACKGROUND

### Field

Embodiments of the disclosure relate to a display device and a display panel.

### Description of Related Art

With the development of technology, the display device may provide a capture function and various detection functions in addition to an image display function. To this end, the display device includes an optical electronic device (also referred to as a light receiving device or sensor), such as a camera and a detection sensor.

Since the optical electronic device receives light from the front of the display device, the optical electronic device should be installed where light reception is easy. Accordingly, conventionally, the camera (camera lens) and the detection sensor had to be installed so as to be exposed on the front surface of the display device. Thus, the bezel of the display panel is widened or a notch or physical hole is formed in the display area of the display panel, and a camera or a detection sensor is installed there.

Therefore, as the display device is equipped with optical electronic devices such as cameras, detection sensors, etc. that perform a specified function by receiving light from the front of the display device, the front of the display device may have a large bezel or the front design of the display device may be restricted.

Further, when the display device includes an optical electronic device, an unexpected deterioration in image quality may occur depending on the structure for including the optical electronic device.

### SUMMARY

Embodiments of the disclosure may provide a display panel and a display device having a light transmission structure in which an optical electronic device may normally receive light (e.g., visible light, infrared light, or ultraviolet light) without exposing the optical electronic device through the front surface of the display device.

Embodiments of the disclosure may provide a display panel and a display device having a unique arrangement structure for a light emitting element and a pixel circuit for driving the light emitting element in an optical area to enhance transmittance of the optical area.

Embodiments of the disclosure may provide a display panel and a display device having a unique connecting structure between a pixel circuit and a light emitting element to enhance transmittance in an optical area.

Embodiments of the disclosure may provide a display panel and a display device capable of preventing an increase the optical bezel area or a change of the shape of the optical bezel area to differ from the designed shape in a display panel requiring a high resolution or a display panel for implementing low power consumption.

In one embodiment, a display device comprises: a light transmittable optical area included in a display area of the display device, the light transmittable optical area configured to display an image; a normal area included in the display area, the normal area around the light transmittable optical area; an optical bezel area included in the display area, the optical bezel area between the light transmittable optical area and the normal area; a plurality of first subpixel circuit units and a plurality of second subpixel circuit units in the optical bezel area, the plurality of first subpixel circuit units including a first subpixel circuit unit and the plurality of second subpixel circuit units including a second subpixel circuit unit; and a plurality of third subpixel circuit units in the normal area, the plurality of third subpixel circuit units including a third subpixel circuit unit, wherein at least one of a length in a first direction and a length in a second direction of the first subpixel circuit unit and at least one of a length in the first direction and a length in the second direction of the second subpixel circuit unit is respectively different from a length in the first direction and a length in the second direction of the third subpixel circuit unit.

In on embodiment, a display panel comprises: a light transmittable optical area included in a display area of the display panel and configured to display an image; a normal area included in the display area, the normal area configured to display the image and positioned around the light transmittable first optical area; an optical bezel area between the light transmittable optical area and the normal area in the display area and comprising a first area and a second area that is different from the first area, the first optical bezel area configured to display the image; and a plurality of subpixel circuit units in the optical bezel area, the plurality of subpixel circuit units including a first subpixel circuit unit in the first area and a second subpixel circuit unit in the second area, wherein one or more dimensions of the first subpixel circuit unit in a plan view of the display panel is different from one or more dimensions of the second subpixel circuit unit in the plan view of the display panel.

There may be provided a display panel and a display device capable of preventing or at least reducing an increase in the optical bezel area or a change of the shape of the optical bezel area to differ from the designed shape by adjusting the size of the subpixel circuit unit disposed in the optical bezel area surrounding the optical area even in a display panel for implementing low power consumption or a display panel requiring a high resolution.

### BRIEF DESCRIPTION OF DRAWINGS

The above and other objects, features, and advantages of the disclosure will be more clearly understood from the following detailed description, taken in conjunction with the accompanying drawings, in which:

FIGS. 1A, 1B, and 1C illustrate a display device according to embodiments of the disclosure;

FIG. 2 is a view illustrating a system configuration of a display device according to embodiments of the disclosure;

FIG. 3 is a view schematically illustrating a display panel according to embodiments of the disclosure;

FIG. 4 schematically illustrates a first optical area of a first type and a normal area around the first optical area in a display panel according to embodiments of the disclosure;

FIG. 5 illustrates light emitting elements and pixel circuits for driving the light emitting elements disposed in a normal area, a first optical bezel area, and a first optical area in a display panel according to embodiments of the disclosure;

FIG. 6 illustrates light emitting elements and pixel circuits for driving the light emitting elements disposed in a normal area, a first optical bezel area, and a first optical area in a display panel according to embodiments of the disclosure;

FIG. 7 is a plan view illustrating a normal area, a first optical bezel area, and a first optical area in a display panel according to embodiments of the disclosure;

FIG. 8 is a cross-sectional view illustrating a first optical bezel area and a first optical area of a display panel according to embodiments of the disclosure;

FIG. 9 is a cross-sectional view illustrating a first optical bezel area and a first optical area of a display panel according to embodiments of the disclosure;

FIG. 10 is a view illustrating an arrangement of emission areas in each of a first optical area, a first optical bezel area, and a normal area in a display panel according to embodiments of the disclosure;

FIG. 11 is a view illustrating a structure in which subpixel circuit units are arranged in one block in a normal area according to embodiments of the disclosure;

FIG. 12 is a view illustrating a structure in which subpixel circuit units are arranged in one block in each an X area and a Y area of a first optical bezel area according to embodiments of the disclosure;

FIG. 13 is a view schematically illustrating a structure in which a plurality of subpixel circuit units are disposed in a first optical bezel area according to embodiments of the disclosure;

FIGS. 14 and 15 are views schematically illustrating a structure of a subpixel circuit unit disposed in a first optical bezel area according to embodiments of the disclosure;

FIG. 16 is a plan view illustrating a structure of a subpixel circuit unit disposed in a first optical bezel area according to embodiments of the disclosure;

FIG. 17 is a view schematically illustrating a plurality of subpixel circuit units disposed in a first optical bezel area and a signal line and a storage capacitor disposed in each subpixel circuit unit according to embodiments of the disclosure; and

FIG. 18 is a view schematically illustrating a normal area and a second optical area in a display panel according to embodiments of the disclosure.

### DETAILED DESCRIPTION

In the following description of examples or embodiments of the disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the disclosure, detailed descriptions of well-known functions and components incorporated herein will be omitted when it is determined that the description may make the subject matter in some embodiments of the disclosure rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of the disclosure. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

Hereinafter, various embodiments of the disclosure are described in detail with reference to the accompanying drawings. In describing the embodiments, descriptions of elements identical to or corresponding to those of the previous embodiments will be omitted. The embodiments are described below with reference thereto.

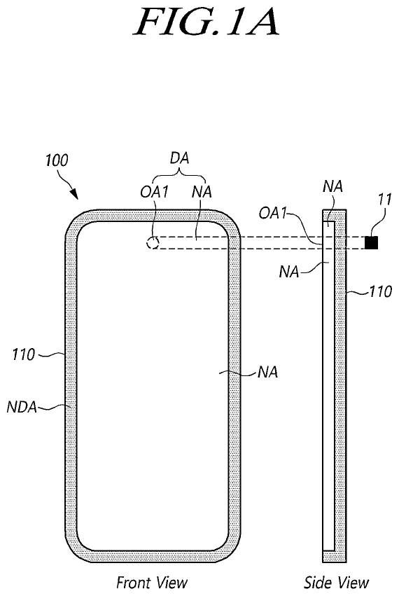

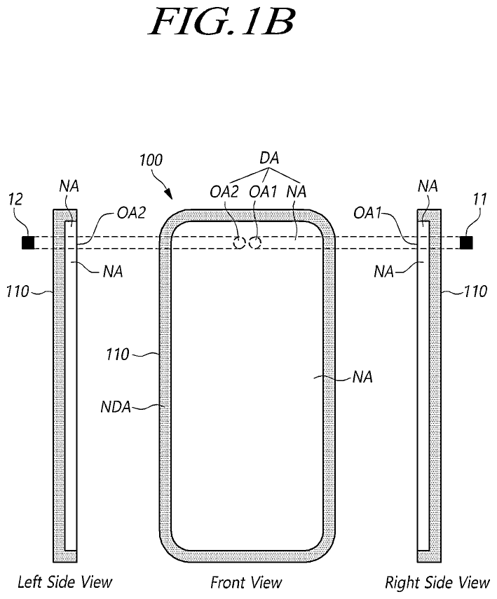

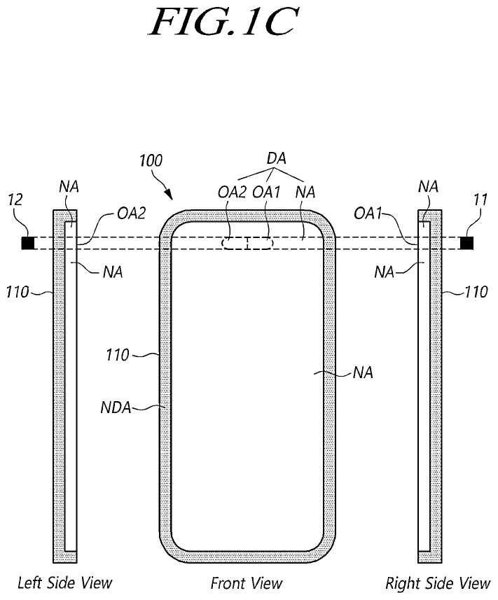

FIGS. 1A, 1B, and 1C illustrate a display device 100 according to embodiments of the disclosure.

Referring to FIGS. 1A, 1B, and 1C, a display device 100 according to embodiments of the disclosure may include a display panel 110 for displaying images and one or more optical electronic devices 11 and 12.

The display panel 110 may include a display area DA in which images (e.g., videos) may be displayed and a non-display area NDA in which the image is not displayed.

A plurality of subpixels may be disposed in the display area DA, and various signal lines for driving the plurality of subpixels may be disposed in the display area AA.

The non-display area NDA may be an area outside the display area DA. In the non-display area NDA, various signal lines may be disposed, and various driving circuits may be connected thereto. The non-display area NDA may be bent to be invisible from the front or may be covered by a case (not shown). The non-display area NDA is also referred to as a bezel or a bezel area.

Referring to FIGS. 1A, 1B, and 1C, in the display device 100 according to embodiments of the disclosure, one or more optical electronic devices 11 and 12 are electronic components that are provided and installed separately from the display panel 110 and positioned under the display panel 110 (side opposite to the viewing surface).

Light enters the front surface (viewing surface) of the display panel 110 and passes through the display panel 110 to one or more optical electronic devices 11 and 12 positioned under the display panel 110 (opposite to the viewing surface). For example, the light passing through the display panel 110 may include visible light, infrared light, or ultraviolet light.

The one or more optical electronic devices 11 and 12 may be devices that receive the light transmitted through the display panel 110 and perform a predetermined function according to the received light. For example, the one or more optical electronic devices 11 and 12 may include one or more of a capture device, such as a camera (image sensor), and a detection sensor, such as a proximity sensor and an illuminance sensor. For example, the detection sensor may be an infrared sensor.

Referring to FIGS. 1A, 1B, and 1C, in the display panel 110 according to embodiments of the disclosure, the display area DA may include a normal area NA and one or more optical areas OA1 and OA2. The one or more optical areas OA1 and OA2 may be areas overlapping the one or more optical electronic devices 11 and 12. In one embodiment, the first optical area OA1 is considered a “first area” of the display area DA and the normal area NA is considered a “second area” of the display area DA in one embodiment.

According to the example of FIG. 1A, the display area DA may include the normal area NA and the first optical area OA1. At least a portion of the first optical area OA1 may overlap the first optical electronic device 11.

According to the example of FIG. 1B, the display area DA may include a normal area NA, a first optical area OA1, and a second optical area OA2. In the example of FIG. 1B, the normal area NA may be present between the first optical area OA1 and the second optical area OA2. At least a portion of the first optical area OA1 may overlap the first optical electronic device 11, and at least a portion of the second optical area OA2 may overlap the second optical electronic device 12.

According to the example of FIG. 1C, the display area DA may include a normal area NA, a first optical area OA1, and a second optical area OA2. In the example of FIG. 1C, the normal area NA is not present between the first optical area OA1 and the second optical area OA2. In other words, the first optical area OA1 and the second optical area OA2 touch each other. At least a portion of the first optical area OA1 may overlap the first optical electronic device 11, and at least a portion of the second optical area OA2 may overlap the second optical electronic device 12.

The one or more optical areas OA1 and OA2 should have both an image display structure and a light transmission structure. In other words, since the one or more optical areas OA1 and OA2 are partial areas of the display area DA, emission areas of subpixels for displaying images should be disposed in the one or more optical areas OA1 and OA2. A light transmission structure for transmitting light to the one or more optical and electronic devices 11 and 12 should be formed in one or more optical areas OA1 and OA2.

The one or more optical electronic devices 11 and 12 are devices that require light reception, but are positioned behind (below, opposite to the viewing surface) the display panel 110 to receive the light transmitted through the display panel 110. The one or more optical electronic devices 11 and 12 are not exposed on the front surface (viewing surface) of the display panel 110. Therefore, when the user looks at the front surface of the display device 110, the optical electronic devices 11 and 12 are not visible to the user.

For example, the first optical electronic device 11 may be a camera, and the second optical electronic device 12 may be a detection sensor, such as a proximity sensor or an illuminance sensor. For example, the detection sensor may be an infrared sensor that detects infrared rays. Conversely, the first optical electronic device 11 may be a detection sensor, and the second optical electronic device 12 may be a camera.

Hereinafter, for convenience of description, it is assumed that the first optical electronic device 11 is a camera and the second electronic device 12 is an infrared (IR)-based detection sensor. The camera may be a camera lens or an image sensor.

If the first optical electronic device 11 is a camera, the camera may be a front camera that is positioned behind (below) the display panel 110 but captures forward of the display panel 110. Accordingly, the user may take a photograph through the camera that is invisible to the viewing surface while viewing the viewing surface of the display panel 110.

The normal area NA and one or more optical areas OA1 and OA2 included in the display area DA are areas that may display images, but the normal area NA is an area that does not require a light transmission structure to be formed, and the one or more optical areas OA1 and OA2 are areas that require a light transmission structure to be formed due to the electronic device 11, 12 being in the one or more optical areas.

Accordingly, the one or more optical areas OA1 and OA2 should have a light transmittance that is higher than or equal to a certain level, and the normal area NA may have no light transmittance or a lower transmittance less than the certain level.

For example, one or more optical areas OA1 and OA2 and the normal area NA may have different resolutions, subpixel placement structures, numbers of subpixels per unit area, electrode structures, line structures, electrode placement structures, or line placement structures.

For example, the number of subpixels per unit area in one or more optical areas OA1 and OA2 may be less than the number of subpixels per unit area in the normal area NA. In other words, the resolution of one or more optical areas OA1 and OA2 may be less than the resolution of the normal area NA. Here, the number of subpixels per unit area may be meant to be equivalent to resolution, or pixel density, or pixel integration degree. For example, the unit for the number of subpixels per unit area may be pixels per inch (PPI), which means the number of pixels in one inch.

For example, the number of subpixels per unit area in the first optical area OA1 may be less than the number of subpixels per unit area in the normal area NA. The number of subpixels per unit area in the second optical area OA2 may be larger than or equal to the number of subpixels per unit area in the first optical area OA1 and be smaller than the number of subpixels per unit area in the normal area NA.

Meanwhile, as one method for increasing the light transmittance of at least one of the first optical area OA1 and the second optical area OA2, a pixel density differential design scheme may be applied as described above. According to the pixel density differential design scheme, the display panel 110 may be designed so that the number of subpixels per unit area of at least one of the first optical area OA1 and the second optical area OA2 is greater than the number of subpixels per unit area of the normal area NA.

However, in some cases, as another method for increasing the transmittance of at least one of the first optical area OA1 and the second optical area OA2, a pixel size differential design scheme may be applied. According to the pixel size differential design scheme, the display panel 110 may be designed so that the number of subpixels per unit area of at least one of the first optical area OA1 and the second optical area OA2 is identical or similar to the number of subpixels per unit area of the normal area NA, and the size of each subpixel (i.e., the size of the emission area) disposed in at least one of the first optical area OA1 and the second optical area OA2 is smaller than the size of each subpixel SP (i.e., the size of the emission area) disposed in the normal area NA.

Hereinafter, for convenience of description, it is assumed in the following description that, of the two schemes (pixel density differential design scheme and pixel size differential design scheme) for increasing the transmittance of at least one of the first optical area OA1 and the second optical area OA2, the pixel density differential design scheme is applied. Accordingly, that the number of subpixels per unit area is small, as described below, may be an expression corresponding to the subpixel size being small, and that the number of subpixels per unit area is large may be an expression corresponding to the subpixel size being large.

The first optical area OA1 may have various shapes, such as a circle, an ellipse, a quadrangle, a hexagon, or an octagon. The second optical area OA2 may have various shapes, such as a circle, an ellipse, a square, a hexagon, or an octagon. The first optical area OA1 and the second optical area OA2 may have the same shape or different shapes.

Referring to FIG. 1C, when the first optical area OA1 and the second optical area OA2 touch, the entire optical area including the first optical area OA1 and the second optical area OA2 may have various shapes, such as a circle, an ellipse, a square, a hexagon, or an octagon. Hereinafter, for convenience of description, each of the first optical area OA1 and the second optical area OA2 is exemplified as having a circular shape.

In the display device 100 according to embodiments of the disclosure, if the first optical electronic device 11 that is not exposed to the outside and is hidden in a lower portion of the display panel 100 is a camera, the display device 100 according to embodiments of the disclosure may be referred to as a display to which under display camera (UDC) technology has been applied.

Accordingly, the display device 100 according to embodiments of the disclosure does not require a notch or camera hole for camera exposure to be formed in the display panel 110, thereby preventing a reduction in the display area DA. Thus, as there is no need to form a notch or camera hole for exposure of the camera in the display panel 110, the size of the bezel area may be reduced, and design restrictions may be freed, thereby increasing the degree of freedom in design.

In the display device 100 according to embodiments of the disclosure, although one or more optical electronic devices 11 and 12 are positioned to be hidden behind the display panel 110, one or more optical electronic devices 11 and 12 should be able to normally perform predetermined functions by normally receiving light.

Further, in the display device 100 according to embodiments of the disclosure, although one or more optical electronic devices 11 and 12 are positioned to be hidden behind the display panel 110 and are positioned to overlap the display area DA, the one or more optical areas OA1 and OA2 overlapping the one or more optical electronic devices 11 and 12 in the display area DA should be capable of normal image display.

Since the above-mentioned first optical area OA1 is designed as a light transmittable area, the image display characteristics in the first optical area OA1 may differ from the image display characteristics in the normal area NA.

Further, in designing the first optical area OA1 to enhance the image display characteristics, the transmittance of the first optical area OA1 may be degraded.

Accordingly, embodiments of the disclosure propose a structure of the first optical area OA1 capable of enhancing light transmittance in the first optical area OA1 without causing an image quality deviation between the first optical area OA1 and the normal area NA.

Further, embodiments of the disclosure propose a structure of the second optical area OA2 capable of enhancing light transmittance in the second optical area OA2 and image quality in the second optical area OA2 for the second optical area OA2, as well as for the first optical area OA1.

Further, in the display device 100 according to embodiments of the disclosure, the first optical area OA1 and the second optical area OA2 are similar in that they are light transmittable areas, but differ in use cases. Therefore, in the display device 100 according to embodiments of the disclosure, the structure of the first optical area OA1 and the structure of the second optical area OA2 may be designed to differ from each other.

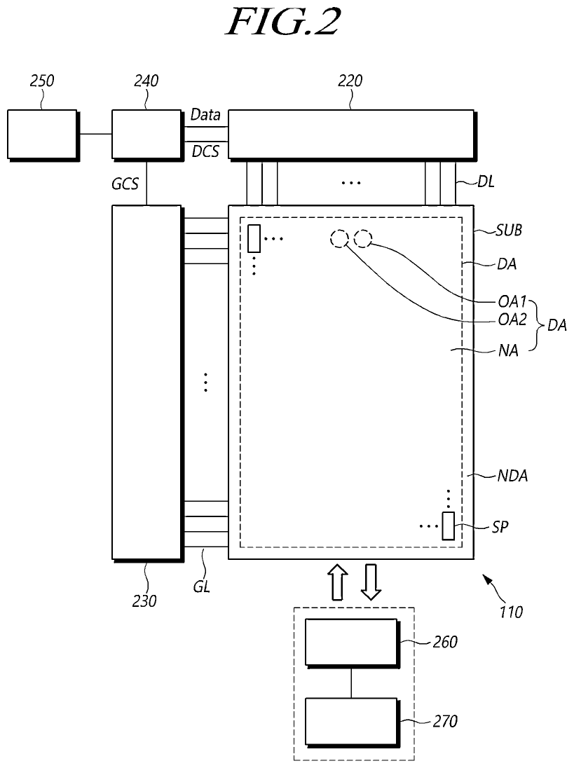

FIG. 2 is a view illustrating a system configuration of a display device 100 according to embodiments of the disclosure.

Referring to FIG. 2, a display device 100 may include a display panel 110 and display driving circuits, as components for displaying images.

The display driving circuits are circuits for driving the display panel 110 and may include a data driving circuit 220, a gate driving circuit 230, and a display controller 240.

The display panel 110 may include the display area DA in which images are displayed and the non-display area NDA in which no image is displayed. The non-display area NDA may be an outer area of the display area DA and be referred to as a bezel area. The entire non-display area NDA or part of the non-display area NDA may be an area visible from the front surface of the display device 100 or an area that is bent and not visible from the front surface of the display device 100.

The display panel 110 may include a substrate SUB and a plurality of subpixels SP disposed on the substrate SUB. The display panel 110 may further include various types of signal lines to drive the plurality of subpixels SP.

The display device 100 according to embodiments of the disclosure may be a liquid crystal display device or a self-emission display device in which the display panel 110 emits light by itself. When the display device 100 according to the embodiments of the disclosure is a self-emission display device, each of the plurality of subpixels SP may include a light emitting element. For example, the display device 100 according to embodiments of the disclosure may be an organic light emitting diode display in which the light emitting element is implemented as an organic light emitting diode (OLED). As another example, the display device 100 according to embodiments of the disclosure may be an inorganic light emitting display device in which the light emitting element is implemented as an inorganic material-based light emitting diode. As another example, the display device 100 according to embodiments of the disclosure may be a quantum dot display device in which the light emitting element is implemented as a quantum dot which is self-emission semiconductor crystal.

The structure of each of the plurality of subpixels SP may vary according to the type of the display device 100. For example, when the display device 100 is a self-emission display device in which the subpixels SP emit light by themselves, each subpixel SP may include a light emitting element that emits light by itself, one or more transistors, and one or more capacitors.

For example, various types of signal lines may include a plurality of data lines DL transferring data signals (also referred to as data voltages or image signals) and a plurality of gate lines GL transferring gate signals (also referred to as scan signals).

The plurality of data lines DL and the plurality of gate lines GL may cross each other. Each of the plurality of data lines DL may be disposed while extending in a first direction. Each of the plurality of gate lines GL may be disposed while extending in a second direction. Here, the first direction may be a column direction and the second direction may be a row direction. The first direction may be the row direction, and the second direction may be the column direction.

The data driving circuit 220 is a circuit for driving the plurality of data lines DL, and may output data signals to the plurality of data lines DL. The gate driving circuit 230 is a circuit for driving the plurality of gate lines GL, and may output gate signals to the plurality of gate lines GL.

The display controller 240 is a device for controlling the data driving circuit 220 and the gate driving circuit 230 and may control driving timings for the plurality of data lines DL and driving timings for the plurality of gate lines GL.

The display controller 240 may supply a data driving control signal DCS to the data driving circuit 220 to control the data driving circuit 220 and may supply a gate driving control signal GCS to the gate driving circuit 230 to control the gate driving circuit 230.

The display controller 240 may receive input image data from the host system 250 and supply image data Data to the data driving circuit 220 based on the input image data.

The data driving circuit 220 may receive digital image data Data from the display controller 240 and may convert the received image data Data into analog data signals and output the analog data signals to the plurality of data lines DL.

The gate driving circuit 230 may receive a first gate voltage corresponding to a turn-on level voltage and a second gate voltage corresponding to a turn-off level voltage, along with various gate driving control signals GCS, generate gate signals, and supply the generated gate signals to the plurality of gate lines GL.

For example, the data driving circuit 220 may be connected with the display panel 110 by a tape automated bonding (TAB) method or connected to a bonding pad of the display panel 110 by a chip on glass (COG) or chip on panel (COP) method or may be implemented by a chip on film (COF) method and connected with the display panel 110.

The gate driving circuit 230 may be connected with the display panel 110 by TAB method or connected to a bonding pad of the display panel 110 by a COG or COP method or may be connected with the display panel 110 according to a COF method. Alternatively, the gate driving circuit 230 may be formed in a gate in panel (GIP) type, in the non-display area NDA of the display panel 110. The gate driving circuit 230 may be disposed on the substrate or may be connected to the substrate. In other words, the gate driving circuit 230 that is of a GIP type may be disposed in the non-display area NDA of the substrate. The gate driving circuit 230 that is of a chip-on-glass (COG) type or chip-on-film (COF) type may be connected to the substrate.

Meanwhile, at least one of the data driving circuit 220 and the gate driving circuit 230 may be disposed in the display area DA of the display panel 110. For example, at least one of the data driving circuit 220 and the gate driving circuit 230 may be disposed not to overlap the subpixels SP or to overlap all or some of the subpixels SP.

The data driving circuit 220 may be connected to one side (e.g., an upper or lower side) of the display panel 110. Depending on the driving scheme or the panel design scheme, data driving circuits 220 may be connected with both the sides (e.g., both the upper and lower sides) of the display panel 110, or two or more of the four sides of the display panel 110.

The gate driving circuit 230 may be connected to one side (e.g., a left or right side) of the display panel 110. Depending on the driving scheme or the panel design scheme, gate driving circuits 230 may be connected with both the sides (e.g., both the left and right sides) of the display panel 110, or two or more of the four sides of the display panel 110.

The display controller 240 may be implemented as a separate component from the data driving circuit 220, or the display controller 140 and the data driving circuit 220 may be integrated into an integrated circuit (IC).

The display controller 240 may be a timing controller used in typical display technology, a control device that may perform other control functions as well as the functions of the timing controller, or a control device other than the timing controller, or may be a circuit in the control device. The display controller 240 may be implemented as various circuits or electronic components, such as an integrated circuit (IC), a field programmable gate array (FPGA), an application specific integrated circuit (ASIC), or a processor.

The display controller 240 may be mounted on a printed circuit board or a flexible printed circuit and may be electrically connected with the data driving circuit 220 and the gate driving circuit 230 through the printed circuit board or the flexible printed circuit.

The display controller 240 may transmit/receive signals to/from the data driving circuit 220 according to one or more predetermined interfaces. The interface may include, e.g., a low voltage differential signaling (LVDS) interface, an embedded clock point-point interface (EPI) interface, and a serial peripheral interface (SPI).

To provide a touch sensing function as well as an image display function, the display device 100 according to embodiments of the disclosure may include a touch sensor and a touch sensing circuit that senses the touch sensor to detect whether a touch occurs by a touch object, such as a finger or pen, or the position of the touch.

The touch sensing circuit may include a touch driving circuit 260 that drives and senses the touch sensor and generates and outputs touch sensing data and a touch controller 270 that may detect an occurrence of a touch or the position of the touch using touch sensing data.

The touch sensor may include a plurality of touch electrodes. The touch sensor may further include a plurality of touch lines for electrically connecting the plurality of touch electrodes and the touch driving circuit 260.

The touch sensor may be present in a touch panel form outside the display panel 110 or may be present inside the display panel 110. When the touch panel, in the form of a touch panel, exists outside the display panel 110, the touch panel is referred to as an external type. When the touch sensor is of the external type, the touch panel and the display panel 110 may be separately manufactured or may be combined during an assembly process. The external-type touch panel may include a touch panel substrate and a plurality of touch electrodes on the touch panel substrate.

When the touch sensor is present inside the display panel 110, the touch sensor may be formed on the substrate SUB, together with signal lines and electrodes related to display driving, during the manufacturing process of the display panel 110.

The touch driving circuit 260 may supply a touch driving signal to at least one of the plurality of touch electrodes and may sense at least one of the plurality of touch electrodes to generate touch sensing data.

The touch sensing circuit may perform touch sensing in a self-capacitance sensing scheme or a mutual-capacitance sensing scheme.

When the touch sensing circuit performs touch sensing in the self-capacitance sensing scheme, the touch sensing circuit may perform touch sensing based on capacitance between each touch electrode and the touch object (e.g., finger or pen). According to the self-capacitance sensing scheme, each of the plurality of touch electrodes may serve both as a driving touch electrode and as a sensing touch electrode. The touch driving circuit 260 may drive all or some of the plurality of touch electrodes and sense all or some of the plurality of touch electrodes.

When the touch sensing circuit performs touch sensing in the mutual-capacitance sensing scheme, the touch sensing circuit may perform touch sensing based on capacitance between the touch electrodes. According to the mutual-capacitance sensing scheme, the plurality of touch electrodes are divided into driving touch electrodes and sensing touch electrodes. The touch driving circuit 260 may drive the driving touch electrodes and sense the sensing touch electrodes.

The touch driving circuit 260 and the touch controller 270 included in the touch sensing circuit may be implemented as separate devices or as a single device. The touch driving circuit 260 and the data driving circuit 220 may be implemented as separate devices or as a single device.

The display device 100 may further include a power supply circuit for supplying various types of power to the display driver integrated circuit and/or the touch sensing circuit.

The display device 100 according to embodiments of the disclosure may be a mobile terminal, such as a smart phone or a tablet, or a monitor or television (TV) in various sizes but, without limited thereto, may be a display in various types and various sizes capable of displaying information or images.

As described above, the display area DA in the display panel 110 may include the normal area NA and one or more optical areas OA1 and OA2. The normal area NA and one or more optical areas OA1 and OA2 are areas capable of displaying an image. However, the normal area NA is an area where a light transmission structure is not required to be formed, and one or more optical areas OA1 and OA2 are areas in which a light transmission structure is to be formed.

As described above, the display area DA in the display panel 110 may include one or more optical areas OA1 and OA2 together with the normal area NA, but for convenience of description, it is assumed that the display area DA includes both the first optical area OA1 and the second optical area OA2 (FIGS. 1B and 1C).

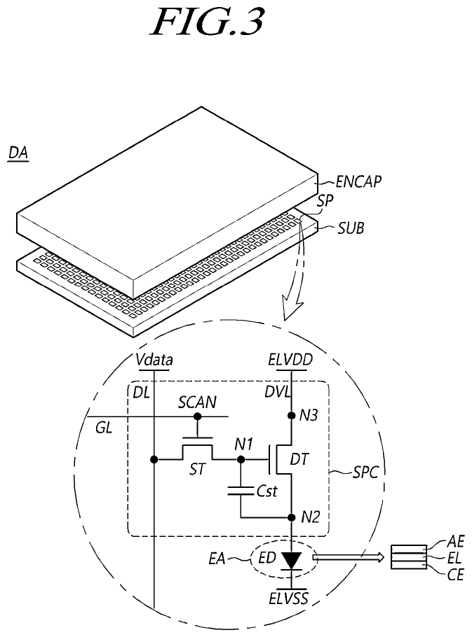

FIG. 3 is a view schematically illustrating a display panel 110 according to embodiments of the disclosure.

Referring to FIG. 3, a plurality of subpixels SP may be disposed in the display area DA of the display panel 110. The plurality of subpixels SP may be disposed in the normal area NA and the first optical area OA1 and the second optical area OA2 included in the display area DA.

Referring to FIG. 3, each of the plurality of subpixels SP may include a light emitting element ED and a pixel circuit SPC configured to drive the light emitting element ED.

Referring to FIG. 3, the pixel circuit SPC may include a driving transistor DT for driving the light emitting element ED, a scan transistor ST for transferring the data voltage Vdata to the first node N1 of the driving transistor DT, and a storage capacitor Cst for maintaining a constant voltage during one frame.

The driving transistor DT may include the first node N1 to which the data voltage may be applied, a second node N2 electrically connected with the light emitting element ED, and a third node N3 to which a driving voltage ELVDD is applied from a driving voltage line DVL. The first node N1 in the driving transistor DT may be a gate node, the second node N2 may be a source node or a drain node, and the third node N3 may be the drain node or the source node. For convenience of description, described below is an example in which the first node N1 in the driving transistor DT is a gate node, the second node N2 is a source node, and the third node N3 is a drain node.

The light emitting element ED may include an anode electrode AE, a light emitting layer EL, and a cathode electrode CE. The anode electrode AE may be a pixel electrode disposed in each subpixel SP and be electrically connected to the second node N2 of the driving transistor DT of each subpixel SP. The cathode electrode CE may be a common electrode commonly disposed in the plurality of subpixels SP, and a base voltage ELVSS may be applied thereto.

For example, the anode electrode AE may be a pixel electrode, and the cathode electrode CE may be a common electrode. Conversely, the anode electrode AE may be a common electrode, and the cathode electrode CE may be a pixel electrode. Hereinafter, for convenience of description, it is assumed that the anode electrode AE is a pixel electrode and the cathode electrode CE is a common electrode.

The light emitting element ED may have a predetermined emission area EA. The emission area EA of the light emitting element ED may be defined as an area where the anode electrode AE, the light emitting layer EL, and the cathode electrode CE overlap.

For example, the light emitting element ED may be an organic light emitting diode (OLED), an inorganic light emitting diode, or a quantum dot light emitting element. When the light emitting element ED is an organic light emitting diode, the light emitting layer EL of the light emitting element ED may include an organic light emitting layer EL including an organic material.

The scan transistor ST may be on/off controlled by a scan signal SCAN, which is a gate signal, applied via the gate line GL and be electrically connected between the first node N1 of the driving transistor DT and the data line DL.

The storage capacitor Cst may be electrically connected between the first node N1 and second node N2 of the driving transistor DT.

The pixel circuit SPC may have a 2T (transistor) 1C (capacitor) structure which includes two transistors DT and ST and one capacitor Cst as shown in FIG. 3 and, in some cases, each subpixel SP may further include one or more transistors or one or more capacitors.

The capacitor Cst may be an external capacitor intentionally designed to be outside the driving transistor DT, but not a parasite capacitor (e.g., Cgs or Cgd) which is an internal capacitor that may be present between the first node N1 and the second node N2 of the driving transistor DT. Each of the driving transistor DT and the scan transistor ST may be an n-type transistor or a p-type transistor.

Since the circuit elements (particularly, the light emitting element ED implemented as an organic light emitting diode (OLED) containing an organic material) in each subpixel SP are vulnerable to external moisture or oxygen, an encapsulation layer ENCAP may be disposed on the display panel 110 to prevent penetration of external moisture or oxygen into the circuit elements (particularly, the light emitting element ED). The encapsulation layer ENCAP may be disposed to cover the light emitting elements ED.

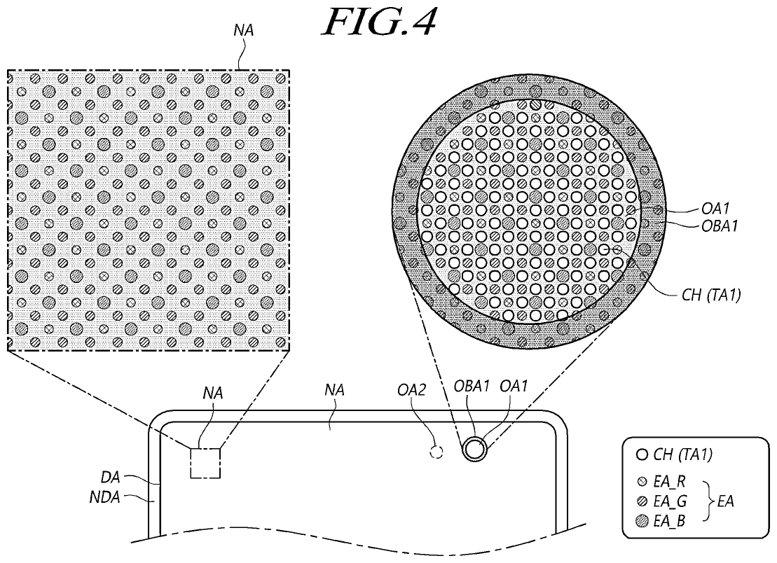

FIG. 4 schematically illustrates a first optical area OA1 of a first type and a normal area NA around the first optical area in a display panel 110 according to embodiments of the disclosure.

Referring to FIG. 4, the display panel 110 according to embodiments of the disclosure may include a display area DA in which images are displayed and a non-display area NDA in which no image is displayed.

Referring to FIG. 4, the display area DA may include a transmittable first optical area OA1 and a normal area NA around the first optical area OA1.

The first optical area OA1 may have a structure of a first type. As such, when the first optical area OA1 is of the first type, the first optical bezel area OBA1 may be disposed outside the first optical area OA1. In embodiments of the disclosure, the first optical bezel area OBA1 may be regarded as a portion of the normal area NA.

In other words, when the first optical area OA1 is of the first type, the display area DA may include the first optical area OA1, the normal area NA positioned outside the first optical area OA1, and the first optical bezel area OBA1, which is an area between the first optical area OA1 and the normal area NA.

Referring to FIG. 4, the first optical area OA1 is an area overlapping the first optical electronic device 11 and may be a transmittable area through which light required for operation of the first optical electronic device 11 may pass.

Here, the light passing through the first optical area OA1 may include light of a single wavelength band or may include light of various wavelength bands. For example, the light passing through the first optical area OA1 may include at least one of visible light, infrared light, or ultraviolet light.

The first optical electronic device 11 may receive light passing through the first optical area OA1 and perform a predetermined operation using the received light. Here, the light received by the first optical electronic device 11 through the first optical area OA1 may include at least one of visible light, infrared light, or ultraviolet light.

For example, when the first optical electronic device 11 is a camera, the light transmitted through the first optical area OA1 and used by the first optical electronic device 11 may include visible light. As another example, when the first optical electronic device 11 is an infrared sensor, the light transmitted through the first optical area OA1 and used in the first optical electronic device 11 may include infrared light (also referred to as infrared light beam or ray).

Referring to FIG. 4, the first optical bezel area OBA1 may be an area positioned outside the first optical area OA1. The normal area NA may be an area positioned outside the first optical bezel area OBA1. Thus, the first optical bezel area OBA1 may be disposed between the first optical area OA1 and the normal area NA.

For example, the first optical bezel area OBA1 may be disposed outside a part of the perimeter of the first optical area OA1 and may be disposed outside the entire perimeter of the first optical area OA1.

When the first optical bezel area OBA1 is disposed outside the entire perimeter of the first optical area OA1, the first optical bezel area OBA1 may have a ring shape surrounding the first optical area OA1.

For example, the first optical area OA1 may have various shapes, such as circular, elliptical, polygonal, or irregular shapes. The first optical bezel area OBA1 may have various ring shapes (e.g., a circular ring shape, an elliptical ring shape, a polygonal ring shape, or an irregular ring shape) surrounding the first optical area OA1 having various shapes.

Referring to FIG. 4, the display area DA may include a plurality of emission areas EA. Since the first optical area OA1, the first optical bezel area OBA1, and the normal area NA are areas included in the display area DA, each of the first optical area OA1, the first optical bezel area OBA1, and the normal area NA may include a plurality of emission areas EA.

For example, the plurality of light emitting areas EA may include a first color light emitting area emitting light of a first color, a second color light emitting area emitting light of a second color, and a third color light emitting area emitting light of a third color.

At least one of the first color emission area, the second color emission area, and the third color emission area may have a different area from the remaining emission areas of different colors.

The first color, the second color, and the third color are different colors and may be various colors. For example, the first color, the second color, and the third color may include red, green, and blue, respectively.

Hereinafter, for convenience of description, a case in which the first color is red, the second color is green, and the third color is blue is exemplified. However, it is not limited thereto.

When the first color is red, the second color is green, and the third color is blue, among the area of the red emission area EA_R, the area of the green emission area EA_G, and the area of the blue emission area EA_B, the area of the blue emission area EA_B may be the largest emission area.

The light emitting element ED disposed in the red emission area EA_R may include a light emitting layer EL emitting red light. The light emitting element ED disposed in the green emission area EA_G may include a light emitting layer EL emitting green light. The light emitting element ED disposed in the blue emission area EA_B may include a light emitting layer EL emitting blue light.

Among the light emitting layer EL emitting red light, the light emitting layer EL emitting green light, and the light emitting layer EL emitting blue light, an organic material included in the light emitting layer EL emitting blue light may be most easily deteriorated.

Since the area of the blue emission area EA_B is designed to be the largest, the density of the current supplied to the light emitting element ED disposed in the blue emission area EA_B may be the smallest. Accordingly, the degree of deterioration of the light emitting element ED disposed in the blue light emitting area EA_B may be similar to the degree of deterioration of the light emitting element ED disposed in the red light emitting area EA_R and the degree of deterioration of the light emitting element ED disposed in the green light emitting area EA_G.

Accordingly, the deterioration deviations between the light emitting element ED disposed in the red light emitting area EA_R, the light emitting element ED disposed in the green light emitting area EA_G, and the light emitting element ED disposed in the blue light emitting area EA_B may be removed or reduced, thereby improving image quality. Further, the deterioration deviations between the light emitting element ED disposed in the red light emitting area EA_R, the light emitting element ED disposed in the green light emitting area EA_G, and the light emitting element ED disposed in the blue light emitting area EA_B may be removed or reduced, thereby reducing the lifetime deviations between the light emitting element ED disposed in the red light emitting area EA_R, the light emitting element ED disposed in the green light emitting area EA_G, and the light emitting element ED disposed in the blue light emitting area EA_B.

Referring to FIG. 4, the first optical area OA1 is a light transmittable area and must have high light transmittance. To that end, the cathode electrode CE may include a plurality of cathode holes CH in the first optical area OA1. In other words, in the first optical area OA1, the cathode electrode CE may include a plurality of cathode holes CH.

Referring to FIG. 4, the cathode electrode CE does not include the cathode hole CH in the normal area NA. In other words, in the normal area NA, the cathode electrode CE does not include the cathode hole CH.

Further, the cathode electrode CE does not include the cathode hole CH in the first optical bezel area OBA1. In other words, in the first optical bezel area OBA1, the cathode electrode CE does not include the cathode hole CH.

In the first optical area OA1, the plurality of cathode holes CH formed in the cathode electrode CE may also be referred to as a plurality of first transmissive areas TA1 or a plurality of openings. Here, in FIG. 4, one cathode hole CH has a circular shape, but may have various shapes other than the circular shape, such as an elliptical shape, a polygonal shape, or an irregular shape.

Referring to FIG. 4, the second optical area OA2 may be disposed adjacent to the first optical area OA1. The arrangement of the emission areas EA in the second optical area OA2 is described below in more detail.

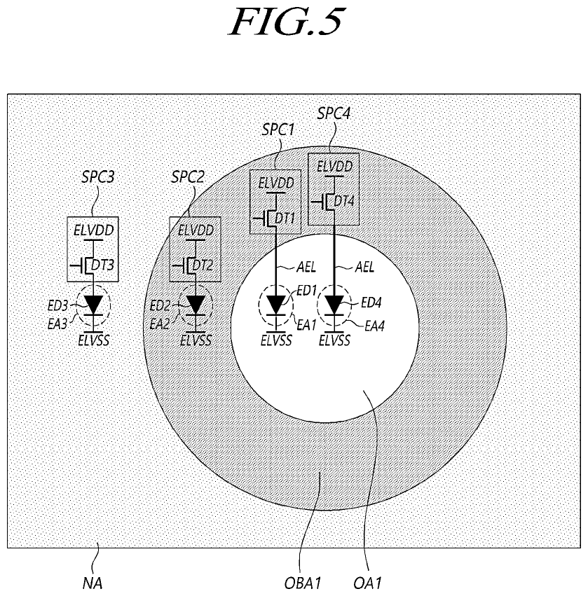

FIG. 5 illustrates light emitting elements ED1, ED2, ED3, and ED4 and pixel circuits SPC1, SPC2, SPC3, and SPC4 for driving the light emitting elements ED1, ED2, ED3, and ED4 disposed in a normal area NA, a first optical bezel area OBA1, and a first optical area OA1 in a display panel 1100 according to embodiments of the disclosure.

However, each of the pixel circuits SPC1, SPC2, SPC3, and SPC4 may include transistors DT and ST and a storage capacitor Cst as shown in FIG. 3. However, for convenience of description, each of the pixel circuits SPC1, SPC2, SPC3, and SPC4 is briefly expressed as a driving transistor DT1, DT2, DT3, and DT4, respectively.

Referring to FIG. 5, the normal area NA, the first optical area OA1, and the first optical bezel area OBA1 may have structural differences as well as positional differences.

As a structural difference, the pixel circuits SPC1, SPC2, SPC3, and SPC may be disposed in the first optical bezel area OBA1 and the normal area NA, but no pixel circuit is disposed in the first optical area OA1. In other words, transistors DT1, DT2, DT3, and DT4 may be disposed in the first optical bezel area OBA1 and the normal area NA, but no transistors are disposed in the first optical area OA1.

The transistors and storage capacitors included in the pixel circuits SPC1, SPC2, SPC3, and SPC4 are components that may reduce transmittance. Accordingly, as the pixel circuits SPC1, SPC2, SPC3, and SPC are not disposed in the first optical area OA1, the transmittance of the first optical area OA1 may be further increased.

The pixel circuits SPC1, SPC2, SPC3, and SPC are disposed only in the normal area NA and the first optical bezel area OBA1, but the light emitting elements ED1, ED2, ED3, and ED4 may be disposed in all of the normal area NA, the first optical bezel area OBA1, and the first optical area OA1.

Referring to FIG. 5, the first light emitting element ED1 is disposed in the first optical area OA1, but the first pixel circuit unit SPC1 for driving the first light emitting element ED1 is not disposed in the first optical area OA1.

Referring to FIG. 5, the first pixel circuit unit SPC1 for driving the first light emitting element ED1 disposed in the first optical area OA1 is not disposed in the first optical area OA1 but may be disposed in the first optical bezel area OBA1.

Described below in greater detail are the normal area NA, the first optical area OA1, and the first optical bezel area OBA1.

Referring to FIG. 5, a plurality of emission areas EA included in the display panel 110 according to embodiments of the disclosure may include a first emission area EA1, a second emission area EA2, and a third emission area EA3. Here, the first emission area EA1 may be included in the first optical area OA1. The second emission area EA2 may be included in the first optical bezel area OBA1. The third emission area EA3 may be included in the normal area NA. Hereinafter, it is assumed that the first emission area EA1, the second emission area EA2, and the third emission area EA3 are emission areas of the same color.

Referring to FIG. 5, the display panel 110 according to embodiments of the disclosure may include a first light emitting element ED1 disposed in a first optical area OA1 and having a first emission area EA1, a second light emitting element ED2 disposed in a first optical bezel area OBA1 and having a second emission area EA2, and a third light emitting element ED3 disposed in a normal area NA and having a third emission area EA3.

Referring to FIG. 5, the display panel 110 according to embodiments of the disclosure may further include a first pixel circuit SPC1 configured to drive the first light emitting element ED1, a second pixel circuit SPC2 configured to drive the second light emitting element ED2, and a third pixel circuit SPC3 configured to drive the third light emitting element ED3.

Referring to FIG. 5, the first pixel circuit SPC1 may include a first driving transistor DT1. The second pixel circuit SPC2 may include a second driving transistor DT2. The third pixel circuit SPC3 may include a third driving transistor DT3.

Referring to FIG. 5, in the display panel 110 according to embodiments of the disclosure, the second pixel circuit SPC2 may be disposed in the first optical bezel area OBA1 in which the corresponding second light emitting element ED2 is disposed, and the third pixel circuit SPC3 may be disposed in the normal area NA in which the corresponding third light emitting element ED3 is disposed.

Referring to FIG. 5, in the display panel 110 according to embodiments of the disclosure, the first pixel circuit SPC1 may not be disposed in the first optical area OA1 where the corresponding first light emitting device ED1 is disposed, but may be disposed in the first optical bezel area OBA1 positioned outside the first optical area OA1. Accordingly, the transmittance of the first optical area OA1 may be increased.

Referring to FIG. 5, the display panel 110 according to the embodiments of the disclosure may further include an anode extension line AEL that electrically connects the first pixel circuit SPC1 disposed in the first optical bezel area OBA1 and the first light emitting element ED1 disposed in the first optical area OA1.

The anode extension line AEL may electrically extend the anode electrode AE of the first light emitting element ED1 to the second node N2 of the first driving transistor DT1 in the first pixel circuit SPC1.

As described above, in the display panel 110 according to embodiments of the disclosure, the first pixel circuit SPC1 for driving the first light emitting element ED1 disposed in the first optical area OA1 may be disposed in the first optical bezel area OBA1, but not disposed in the first optical area OA1. Such a structure is also referred to as an anode extension structure. Accordingly, the first type of the first optical area OA1 is also referred to as an anode extension type.

When the display panel 110 according to embodiments of the disclosure has the anode extension structure, the whole or a portion of the anode extension line AEL may be disposed in the first optical area OA1, and the anode extension line AEL may include a transparent line. Accordingly, even when the anode extension line AEL connecting the first pixel circuit SPC1 and the first light emitting element ED1 is disposed in the first optical area OA1, it is possible to prevent a drop in transmittance.

Referring to FIG. 5, the plurality of emission areas EA may further include a fourth emission area EA4 that emits light of the same color as the first emission area EA1 and is included in the first optical area OA1.

Referring to FIG. 5, the fourth emission area EA4 may be disposed adjacent to the first emission area EA1 in a row direction or column direction.

Referring to FIG. 5, the display panel 110 according to embodiments of the disclosure may further include a fourth light emitting element ED4 disposed in the first optical area OA1 and having a fourth emission area EA4, and a fourth pixel circuit SPC4 configured to drive the fourth light emitting element ED4.

Referring to FIG. 5, the fourth pixel circuit SPC4 may include a fourth driving transistor DT4. For convenience of description, the scan transistor ST and the storage capacitor Cst included in the fourth pixel circuit SPC4 are omitted from FIG. 5.

Referring to FIG. 5, the fourth pixel circuit SPC4 is a circuit for driving the fourth light emitting element ED4 disposed in the first optical area OA1, but may be disposed in the first optical bezel area OBA1.

Referring to FIG. 5, the display panel 110 according to embodiments of the disclosure may further include an anode extension line AEL that electrically connects the fourth pixel circuit SPC4 and the fourth light emitting element ED4.

The whole or a portion of the anode extension line AEL may be disposed in the first optical area OA1, and the anode extension line AEL may include a transparent line.

As described above, the first pixel circuit SPC1 disposed in the first optical bezel area OBA1 may drive one light emitting element ED1 disposed in the first optical area OA1. This circuit unit connection scheme is called a one-to-one (1:1) circuit unit connection scheme.

Accordingly, the number of pixel circuits SPC disposed in the first optical bezel area OBA1 may significantly increase. The structure of the first optical bezel area OBA1 may become complicated and the aperture ratio (or emission area) of the first optical bezel area OBA1 may decrease.

To increase the aperture ratio (or emission area) of the first optical bezel area OBA1 despite having the anode extension structure, the display device 100 according to embodiments of the disclosure may have a 1:N (where N is 2 or more) circuit unit connection scheme.

According to the 1:N circuit unit connection scheme, the first pixel circuit SPC1 disposed in the first optical bezel area OBA1 may simultaneously drive two or more light emitting elements ED disposed in the first optical area OA1.

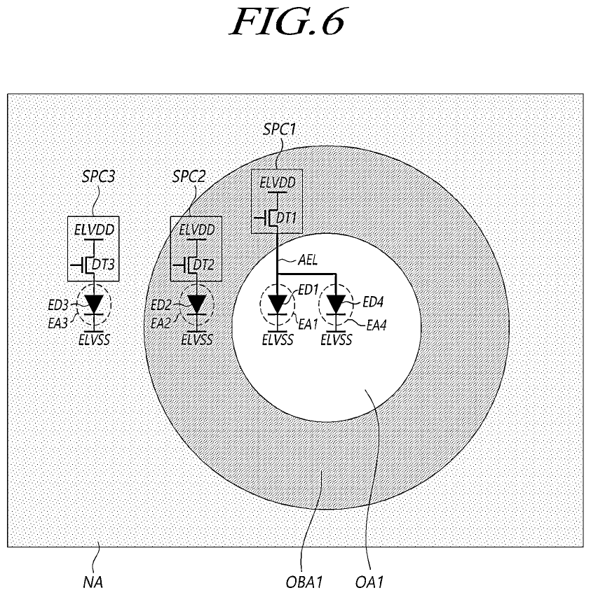

FIG. 6 illustrates an example in which, for convenience of description, a 1:2 circuit unit connection scheme is applied, that is, the first pixel circuit SPC1 disposed in the first optical bezel area OBA1 simultaneously drives two or more light emitting elements ED1 and ED4 disposed in the first optical area OA1.

FIG. 6 illustrates light emitting elements ED1, ED2, ED3, and ED4 and pixel circuits SPC1, SPC2, and SPC3 for driving the light emitting elements ED1, ED2, ED3, and ED4 disposed in a normal area NA, a first optical bezel area OBA1, and a first optical area OA1 in a display panel 1100 according to embodiments of the disclosure.

Referring to FIG. 6, the fourth light emitting element ED4 disposed in the first optical area OA1 may be driven by the first pixel circuit SPC1 for driving the first light emitting element ED1 disposed in the first optical area OA1. In other words, the first pixel circuit SPC1 disposed in the first optical bezel area OBA1 may be configured to drive the first light emitting element ED1 and the fourth light emitting element ED4 disposed in the first optical area OA1 together.

Accordingly, although the display panel 110 has the anode extension structure, the number of pixel circuits SPC disposed in the first optical bezel area OBA1 may be reduced, thereby increasing the opening and emission area of the first optical bezel area OBA1.

In FIG. 6, the first light emitting element ED1 and the fourth light emitting element ED4 driven together by the first pixel circuit SPC1 disposed in the first optical bezel area OBA1 are light emitting elements emitting light of the same color, and may be light emitting elements adjacent to each other in the row direction or column direction.

Referring to FIG. 6, the anode extension line AEL may connect the first pixel circuit SPC1 disposed in the first optical bezel area OBA1 to the first light emitting element ED1 and the fourth light emitting element ED4 disposed in the first optical area OA1.

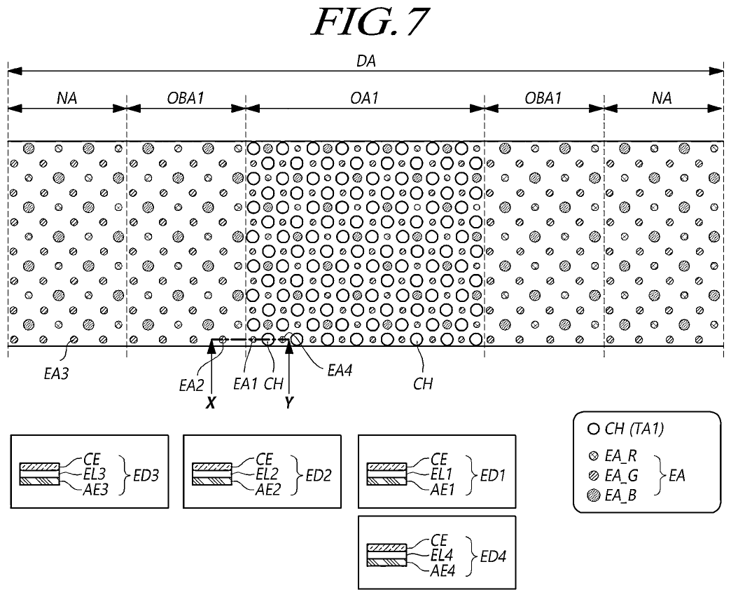

FIG. 7 is a plan view illustrating a normal area NA, a first optical bezel area OBA1, and a first optical area OA1 in a display panel according to embodiments of the disclosure.

Referring to FIG. 7, in the display panel 110 according to embodiments of the disclosure, the plurality of emission areas EA disposed in each of the normal area NA, the first optical bezel area OBA, and the first optical area OA1 may include a red emission area EA_R, a green emission area EA_G, and a blue emission area EA_B.

Referring to FIG. 7, in the display panel 110 according to embodiments of the disclosure, the cathode electrode CE may be commonly disposed in the normal area NA, the first optical bezel area OBA1, and the first optical area OA1.

The cathode electrode CE may include a plurality of cathode holes CH, and the plurality of cathode holes CH of the cathode electrode CE may be disposed in the first optical area OA1.

The normal area NA and first optical bezel area OBA1 may be an area where light is not transmissible, and the first optical area OA1 may be an area where light is transmissible. Thus, the transmittance in the first optical area OA1 may be higher than the transmittance in the first optical bezel area OBA1 and normal area NA.

The entire first optical area OA1 may be the area through which light may be transmitted, and the plurality of cathode holes CH within the first optical area OA1 may be first transmission areas TA1 through which light may be better transmitted. In other words, the remaining area of the first optical area OA1 except for the plurality of cathode holes CH may be an area through which light may be transmitted, and the transmittance of the plurality of cathode holes CH in the first optical area OA1 may be higher than the transmittance of the remaining area of the first optical area OA1 except for the plurality of cathode holes CH.

In contrast, the plurality of cathode holes CH in the first optical area OA1 may be the transmission area TA through which light may be transmitted, and the remaining area of the first optical area OA1 except for the plurality of cathode holes CH may be an area where light is not transmitted.

Referring to FIG. 7, the arrangement of the emission areas EA in the first optical area OA1, the arrangement of the emission areas EA in the first optical bezel area OBA1, and the arrangement of the emission areas EA in the normal area NA may be identical to each other.

Referring to FIG. 7, the plurality of emission areas EA may include a first emission area EA1 included in the first optical area OA1, a second emission area EA2 emitting light of the same color as the first emission area EA1 and included in a first optical bezel area OBA1, and a third emission area EA3 emitting light of the same color as the first emission area EA1 and included in the normal area NA.

Referring to FIG. 7, the plurality of emission areas EA may further include a fourth emission area EA4 that emits light of the same color as the first emission area EA1 and is included in the first optical area OA1.

Referring to FIG. 7, the display panel 110 according to embodiments of the disclosure may include a first anode electrode AE1 disposed in the first optical area OA1, a second anode electrode AE2 disposed in the first optical bezel area OBA1, a third anode electrode AE3 disposed in the normal area NA, and a fourth anode electrode AE4 disposed in the first optical area OA1.

The display panel 110 according to embodiments of the disclosure may further include a cathode electrode CE disposed in common with the normal area NA, the first optical bezel area OBA1, and the first optical area OA1.

The display panel 110 according to embodiments of the disclosure may include a first light emitting layer EL1 disposed in the first optical area OA1, a second light emitting layer EL2 disposed in the first optical bezel area OBA1, a third light emitting layer EL3 disposed in the normal area NA, and a fourth light emitting layer EL4 disposed in the first optical area OA1.

The first to fourth light emitting layers EL4 may be light emitting layers that emit light of the same color. In this case, the first to fourth light emitting layers EL4 may be separately disposed or be integrated as one layer.

Referring to FIG. 7, the first light emitting element ED1 may be formed by the first anode electrode AE1, the first light emitting layer EL1, and the cathode electrode CE, the second light emitting element ED2 may be formed by the second anode electrode AE2, the second light emitting layer EL2, and the cathode electrode CE, the third light emitting element ED3 may be formed by the third anode electrode AE3, the third light emitting layer EL3, and the cathode electrode CE, and the fourth light emitting element ED4 may be formed by the fourth anode electrode AE4, the fourth light emitting layer EL4, and the cathode electrode CE.

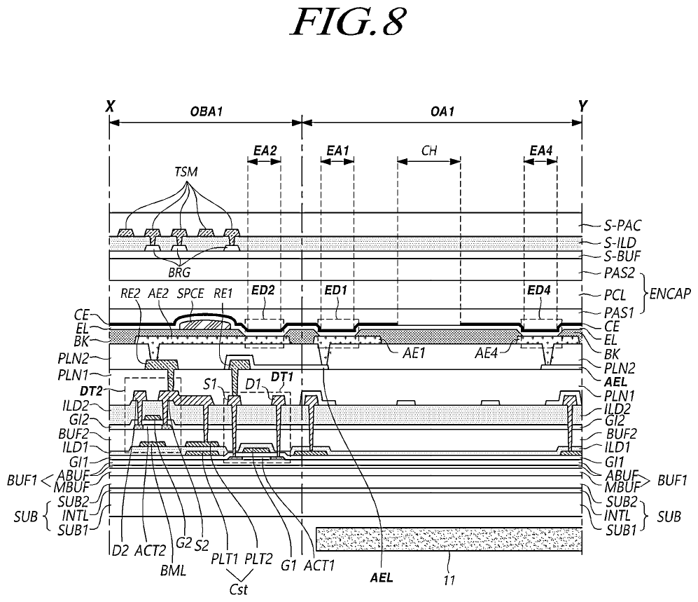

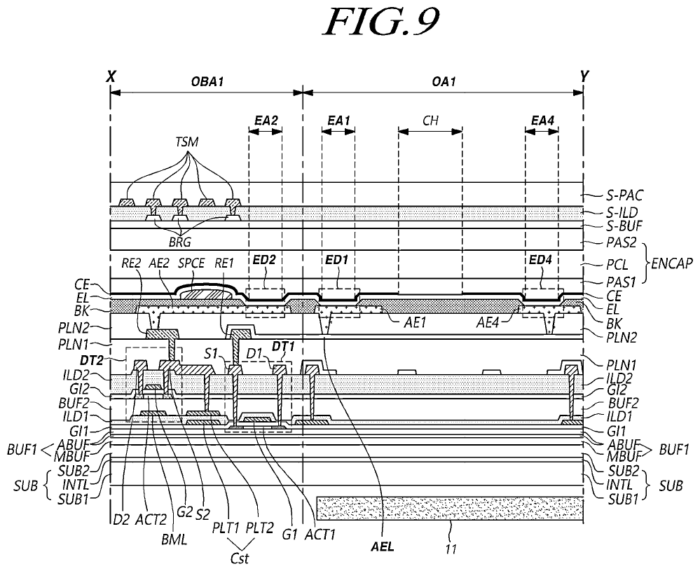

Hereinafter, the cross-sectional structure taken along the X-Y line of FIG. 7 is described in more detail through FIGS. 8 and 9.

The portion taken along line X-Y of FIG. 7 includes a portion of the first optical bezel area OBA1 and a portion of the optical area OA1 with respect to the boundary between the first optical bezel area OBA1 and the first optical area OA1.

The portion taken along line X-Y of FIG. 7 may include the first light emitting area EA1 and the fourth light emitting area EA4 included in the first optical area OA1, and the second light emitting area EA2 included in the first optical bezel area OBA1. The first emitting area EA1, fourth emitting area EA4, and second emitting area EA2 are examples of emission areas EAs that emit the same color of light.

FIG. 8 is a cross-sectional view illustrating a first optical bezel area OBA1 and a first optical area OA1 of a display panel 110 according to embodiments of the disclosure. However, FIG. 8 is a cross-sectional view when the 1:1 circuit connection scheme is applied as in FIG. 5.

Referring to FIG. 8, when viewed in a vertical structure, the display panel 110 may include a transistor forming part, a light emitting element forming part, and an encapsulation part.

The transistor forming part may include a substrate SUB, a first buffer layer BUF1 on the substrate SUB, and various transistors DT1 and DT2, storage capacitor Cst, and various electrodes or signal lines formed on the first buffer layer BUF.

The substrate SUB may include a first substrate SUB1 and a second substrate SUB2. An intermediate film INTL may be present between the first and second substrates SUB1 and SUB2. For example, the intermediate film INTL may be an inorganic film and may block moisture penetration.

The first buffer layer BUF1 may be a single film or multi-film structure. When the first buffer layer BUF1 is formed in a multi-film structure, the first buffer layer BUF1 may include a multi-buffer layer MBUF and an active buffer layer ABUF.

Various transistors DT1 and DT2, storage capacitor Cst, and various electrodes or signal lines may be formed on the first buffer layer BUF1.

For example, the transistors DT1 and DT2 formed on the first buffer layer BUF1 are formed of the same material and on the same layer. Alternatively, as illustrated in FIG. 8, among the transistors DT1 and DT2, the first driving transistor DT1 and the second driving transistor DT2 may be formed of different materials and may be positioned on different layers.

Referring to FIG. 8, the first driving transistor DT1 may be a driving transistor DT for driving the first light emitting element ED1 included in the first optical area OA1, and the second driving transistor DT2 may be a driving transistor DT for driving the second light emitting element ED2 included in the first optical bezel area OBA1.

In other words, the first driving transistor DT1 may be a driving transistor included in the first pixel circuit SPC1 for driving the first light emitting element ED1 included in the first optical area OA1, and the second driving transistor DT2 may be a driving transistor included in the second pixel circuit SPC2 for driving the second light emitting element ED2 included in the first optical bezel area OBA1.

The formation of the first driving transistor DT1 and the second driving transistor DT2 is described below.

The first driving transistor DT1 may include a first active layer ACT1, a first gate electrode G1, a first source electrode S1, and a first drain electrode D1.

The second driving transistor DT2 may include a second active layer ACT2, a second gate electrode G2, a second source electrode S2, and a second drain electrode D2.

The second active layer ACT2 of the second driving transistor DT2 may be positioned higher than the first active layer ACT1 of the first driving transistor DT1.

A first buffer layer BUF1 may be disposed under the first active layer ACT1 of the first driving transistor DT1, and a second buffer layer BUF2 may be disposed under the second active layer ACT2 of the second driving transistor DT2.

In other words, the first active layer ACT1 of the first driving transistor DT1 may be positioned on the first buffer layer BUF1, and the second active layer ACT2 of the second driving transistor DT2 may be positioned on the second buffer layer BUF2. Here, the second buffer layer BUF2 may be positioned higher than the first buffer layer BUF1.

The first active layer ACT1 of the first driving transistor DT1 may be disposed on the first buffer layer BUF1, and a first gate insulation film GI1 may be formed on the first active layer ACT1 of the first driving transistor DT1. The first gate electrode G1 of the first driving transistor DT1 may be disposed on the first gate insulation film GI1, and a first inter-layer insulation film ILD1 may be disposed on the first gate electrode G1 of the first driving transistor DT1.

Here, the first active layer ACT1 of the first driving transistor DT1 may include a first channel area overlapping the first gate electrode G1, a first source connection area positioned on one side of the first channel area, and a channel area, and a first drain connection area positioned on the other side of the channel area.

A second buffer layer BUF2 may be disposed on the first inter-layer insulation film ILD1.

The second active layer ACT2 of the second driving transistor DT2 may be disposed on the second buffer layer BUF2, and a second gate insulation film GI2 may be disposed on the second active layer ACT2. The second gate electrode G2 of the second driving transistor DT2 may be disposed on the second gate insulation film GI2, and a second inter-layer insulation film ILD2 may be disposed on the second gate electrode G2.

Here, the second active layer ACT2 of the second driving transistor DT2 may include a second channel area overlapping the second gate electrode G2, a second source connection area positioned on one side of the second channel area, and a second drain connection area positioned on the other side of the channel area.

The first source electrode S1 and the first drain electrode D1 of the first driving transistor DT1 may be disposed on the second inter-layer insulation film ILD2. The second source electrode S2 and the second drain electrode D2 of the second driving transistor DT2 may be disposed on the second inter-layer insulation film ILD2.

The first source electrode S1 and the first drain electrode D1 of the first driving transistor DT1 may be connected with the first source connection area and the first drain connection area, respectively, of the first active layer ACT1 through the through holes of the second inter-layer insulation film ILD2, the second gate insulation film GI2, the second buffer layer BUF2, the first inter-layer insulation film ILD1, and the first gate insulation film GI1.

The second source electrode S2 and the second drain electrode D21 of the second driving transistor DT2 may be connected with the second source connection area and the second drain connection area, respectively, of the second active layer ACT2 through the through holes in the second inter-layer insulation film ILD2 and the second gate insulation film GI2.

In FIG. 8, only the first driving transistor DT1 and the storage capacitor Cst included in the second pixel circuit SPC2 are shown, with other transistors omitted. In FIG. 8, only the first driving transistor DT1 included in the first pixel circuit SPC1 is shown, with other transistors and storage capacitor omitted.

Referring to FIG. 8, the storage capacitor Cst included in the second pixel circuit SPC2 may include a first capacitor electrode PLT1 and a second capacitor electrode PLT2.

The first capacitor electrode PLT1 may be electrically connected to the second gate electrode G2 of the second driving transistor DT2, and the second capacitor electrode PLT2 may be electrically connected to the second source electrode S2 of the second driving transistor DT2.

Meanwhile, referring to FIG. 8, a lower metal BML may be disposed under the second active layer ACT2 of the second driving transistor DT2. The lower metal BML may overlap the whole or part of the second active layer ACT2.

For example, the lower metal BML may be electrically connected to the second gate electrode G2. As another example, the lower metal BML may serve as a light shield to block the light introduced from thereunder. In this case, the lower metal BML may be electrically connected to the second source electrode S2.

The first driving transistor DT1 is a transistor for driving the first light emitting element ED1 disposed in the first optical area OA1, but may be disposed in the first optical bezel area OBA1.

The second driving transistor DT2 is a transistor for driving the second light emitting element ED2 disposed in the first optical bezel area OBA1, and may be disposed in the first optical bezel area OBA1.

Referring to FIG. 8, a first planarization layer PLN1 may be disposed on the first driving transistor DT1 and the second driving transistor DT2. In other words, the first planarization layer PLN1 may be disposed on the first source electrode S1 and the first drain electrode D2 of the first driving transistor DT1 and the second source electrode S2 and the second drain electrode D2 of the second driving transistor DT2.

Referring to FIG. 8, a first relay electrode RE1 and a second relay electrode RE2 may be disposed on the first planarization layer PLN1.

Here, the first relay electrode RE1 may be an electrode that relays an electrical connection between the first source electrode S1 of the first driving transistor DT1 and the first anode electrode AE1 of the first light emitting element ED1. The second relay electrode RE2 may be an electrode that relays an electrical connection between the second source electrode S2 of the second driving transistor DT2 and the second anode electrode AE2 of the second light emitting element ED2.

The first relay electrode RE1 may be electrically connected to the first source electrode S1 of the first driving transistor DT1 through a hole in the first planarization layer PLN1. The second relay electrode RE2 may be electrically connected to the second source electrode S2 of the second driving transistor DT2 through another hole in the first planarization layer PLN1.

Referring to FIG. 8, the first relay electrode RE1 and the second relay electrode RE2 may be disposed in the first optical bezel area OBA1.

Meanwhile, referring to FIG. 8, the anode extension line AEL may be connected to the first relay electrode RE1 and may extend from the first optical bezel area OBA1 to the first optical area OA1.

Referring to FIG. 8, the anode extension line AEL is a metal layer formed on the first relay electrode RE1 and may be formed of a transparent material.

Referring to FIG. 8, a second planarization layer PLN2 may be disposed covering the first relay electrode RE1, the second relay electrode RE2, and the anode extension line AEL.

Referring to FIG. 8, a light emitting element forming part may be positioned on the second planarization layer PNL2.

Referring to FIG. 8, the light emitting element forming part may include a first light emitting element ED1, a second light emitting element ED2, and a fourth light emitting element ED4 formed on the second planarization layer PNL2.

Referring to FIG. 8, the first light emitting element ED1 and the fourth light emitting element ED4 may be disposed in the first optical area OA1, and the second light emitting element ED2 may be disposed in the first optical bezel area OBA1.

In the example of FIG. 8, the first light emitting element ED1, the second light emitting element ED2, and the fourth light emitting element ED4 are light emitting elements emitting light of the same color. Hereinafter, it is assumed that the respective light emitting layers EL of the first light emitting element ED1, the second light emitting element ED2, and fourth light emitting element ED4 are formed in common, although they may be formed separately.

Referring to FIG. 8, the first light emitting element ED1 may be formed in an area where the first anode electrode AE1, the light emitting layer EL, and the cathode electrode CE overlap. The second light emitting element ED2 may be formed in an area where the second anode electrode AE2, the light emitting layer EL, and the cathode electrode CE overlap. The fourth light emitting element ED4 may be formed in an area where the fourth anode electrode AE4, the light emitting layer EL, and the cathode electrode CE overlap.

Referring to FIG. 8, the first anode electrode AE1, the second anode electrode AE2, and the fourth anode electrode AE4 may be disposed on the second planarization layer PLN2.

The second anode electrode AE2 may be connected to the second relay electrode RE2 through a hole in the second planarization layer PLN2.

The first anode electrode AE1 may be connected to the anode extension line AEL extending from the first optical bezel area OBA1 to the first optical area OA1 through another hole in the second planarization layer PLN2.

The fourth anode electrode AE4 may be connected to another anode extension line AEL extending from the first optical bezel area OBA1 to the first optical area OA1 through another hole in the second planarization layer PLN2.

Referring to FIG. 8, a bank BK may be disposed on the first anode electrode AE1, the second anode electrode AE2, and the fourth anode electrode AE4.

The bank BK may include a plurality of bank holes. The respective portions of the first anode electrode AE1, the second anode electrode AE2, and the fourth anode electrode AE4 may be exposed through the plurality of bank holes. In other words, the plurality of bank holes formed in the bank BK may overlap the respective portions of the first anode electrode AE1, the second anode electrode AE2, and the fourth anode electrode AE4.

Referring to FIG. 8, a light emitting layer EL may be disposed on the bank BK. The light emitting layer EL may contact a portion of the first anode electrode AE1, a portion of the second anode electrode AE2, and a portion of the fourth anode electrode AE4 through a plurality of bank holes.

Referring to FIG. 8, at least one space SPCE may be present between the light emitting layer EL and the bank BK.

Referring to FIG. 8, the cathode electrode CE may be disposed on the light emitting layer EL. The cathode electrode CE may include a plurality of cathode holes CH. A plurality of cathode holes CH formed in the cathode electrode CE may be disposed in the first optical area OA1.

One cathode hole CH formed through the thickness of the cathode electrode CE illustrated in FIG. 8 is a cathode hole positioned between the first emission area EA1 and the fourth emission area EA4.

Referring to FIG. 8, an encapsulation part may be positioned on the cathode electrode CE. The encapsulation part may include an encapsulation layer ENCAP formed on the cathode electrode CE.

Referring to FIG. 8, the encapsulation layer ENCAP may be a layer that prevents penetration of moisture or oxygen into the light emitting elements ED1, ED2, and ED4 disposed under the encapsulation layer ENCAP. In particular, the encapsulation layer ENCAP may prevent penetration of moisture or oxygen into the light emitting layer EL, which may include an organic film. Here, the encapsulation layer ENCAP may be composed of a single film or a multi-film structure.

Referring to FIG. 8, the encapsulation layer ENCAP may include a first encapsulation layer PAS1, a second encapsulation layer PCL, and a third encapsulation layer PAS2. The first encapsulation layer PAS1 and the third encapsulation layer PAS2 may be inorganic films, and the second encapsulation layer PCL may be an organic layer.

As the second encapsulation layer PCL is formed of an organic film, the second encapsulation layer PCL may serve as a planarization layer.

Meanwhile, the display panel 110 according to embodiments of the disclosure may include a touch sensor. In this case, the display panel 110 according to embodiments of the disclosure may include a touch sensor portion formed on the encapsulation layer ENCAP.

Referring to FIG. 8, the touch sensor portion may include touch sensor metals TSM and bridge metals BRG and may further include insulation film components, such as a sensor buffer layer S-BUF, a sensor inter-layer insulation film S-ILD, and a sensor protection layer S-PAC.

The sensor buffer layer S-BUF may be disposed on the encapsulation layer ENCAP. The bridge metals BRG may be disposed on the sensor buffer layer S-BUF. The sensor inter-layer insulation film S-ILD may be disposed on the bridge metals BRG.

The touch sensor metals TSM may be disposed on the sensor inter-layer insulation film S-ILD. Some of the touch sensor metals TSM may be connected to the corresponding bridge metal BRG through a hole in the sensor inter-layer insulation film S-ILD.

Referring to FIG. 8, the touch sensor metals TSM and the bridge metals BRG may be disposed in the first optical bezel area OBA1. The touch sensor metals TSM and the bridge metals BRG may be disposed not to overlap the second emission area EA2 of the first optical bezel area OBA1.

The plurality of touch sensor metals TSM may configure one touch electrode (or one touch electrode line) and may be disposed in a mesh form and electrically connected. Some of the touch sensor metals TSM and some others of the touch sensor metals TSM may be electrically connected through a bridge metal BRG, configuring one touch electrode (or one touch electrode line).

The sensor protection layer S-PAC may be disposed while covering the touch sensor metals TSM and the bridge metals BRG.

Meanwhile, when the display panel 110 is of a type that incorporates touch sensors, at least a portion of the touch sensor metal TSM positioned on the encapsulation layer ENCAP in the display area DA may extend and be disposed along the outer inclined surface of the encapsulation layer ENCAP to electrically connect to a pad positioned further outside the outer inclined surface of the encapsulation layer ENCAP. Here, the pad may be disposed in the non-display area NDA and may be a metal pattern to which the touch driving circuit 260 is electrically connected.

The display panel 110 according to embodiments of the disclosure may further include a bank BK positioned on the first anode electrode AE1 and having a bank hole exposing a portion of the first anode electrode AE1 and a light emitting layer EL positioned on the bank BK and contacting a portion of the first anode electrode AE1 exposed through the bank hole.

The bank hole formed in the bank BK may not overlap the plurality of cathode holes CH. At the point where the cathode hole CH is positioned, the bank BK is not depressed or bored through. Therefore, at the point where the cathode hole CH is positioned, the second planarization layer PLN2 and the first planarization layer PLN1 positioned under the bank BK are not depressed or bored through either.

An upper surface of the bank BK positioned under the plurality of cathode holes CH may be in a flat state without being damaged, meaning that the insulation layer, metal pattern (electrodes or lines), or light emitting layer EL positioned under the cathode electrode CE is not damaged by the process of forming the plurality of cathode holes CH in the cathode electrode CE.

The process of forming the plurality of cathode holes CH in the cathode electrode CE is briefly described below. A specific mask pattern is deposited in positions where a plurality of cathode holes CH are to be formed, and a cathode electrode material is deposited thereon. Accordingly, the cathode electrode material may be deposited only in an area without the specific mask pattern, so that the cathode electrode CE having a plurality of cathode holes CH may be formed. For example, the specific mask pattern may include an organic material. The cathode electrode material may include a magnesium-silver (Mg—Ag) alloy.

Meanwhile, after the cathode electrode CE having the plurality of cathode holes CH is formed, the display panel 110 may be in a state in which the specific mask pattern is completely removed or in a state in which the whole or part of the specific mask pattern remains.

The display panel 110 according to embodiments of the disclosure may include a first driving transistor DT1 disposed in the first optical bezel area OBA1 to drive the first light emitting element ED1 disposed in the first optical area OA1 and a second driving transistor DT2 disposed in the first optical bezel area OBA1 to drive the second light emitting element ED2 disposed in the first optical bezel area OBA1.

The display panel 110 according to embodiments of the disclosure may further include a first planarization layer PLN1 disposed on the first driving transistor DT1 and the second driving transistor DT2, a first relay electrode RE1 positioned on the first planarization layer PLN1 and electrically connected to the first source electrode S1 of the first driving transistor DT1 through a hole of the first planarization layer PLN1, a second relay electrode RE2 positioned on the first planarization layer PLN1 and electrically connected to the second source electrode S2 of the second driving transistor DT2 through another hole of the first planarization layer PLN1, and a second planarization layer PLN2 disposed on the first relay electrode RE1 and the second relay electrode RE2.

The display panel 110 according to embodiments of the disclosure may further include an anode extension line AEL connecting the first relay electrode RE1 and the first anode electrode AE1 and positioned on the first planarization layer PLN1.

The second anode electrode AE2 may be electrically connected to the second relay electrode RE2 through a hole in the second planarization layer PLN2, and the first anode electrode AE1 may be electrically connected to the anode extension line AEL through another hole in the second planarization layer PLN2.

The whole or a portion of the anode extension line AEL may be disposed in the first optical area OA, and the anode extension line AEL may include a transparent material.

The first pixel circuit SPC1 may include a first driving transistor DT1 for driving the first light emitting element ED1. The second pixel circuit SPC2 may include a second driving transistor DT2 for driving the second light emitting element ED2.

The first active layer ACT1 of the first driving transistor DT1 and the second active layer ACT2 of the second driving transistor DT2 may be different from each other.

The display panel 110 according to embodiments of the disclosure may further include a substrate SUB, a first buffer layer BUF1 disposed between the substrate SUB and the first driving transistor DT1, and a second buffer layer BUF2 disposed between the first driving transistor DT1 and the second driving transistor DT2.

The first active layer ACT1 of the first driving transistor DT1 and the second active layer ACT2 of the second driving transistor DT2 may comprise different semiconductor materials.

For example, the second active layer ACT2 of the second driving transistor DT2 may include an oxide semiconductor material. For example, the oxide semiconductor material may include indium gallium zinc oxide (IGZO), indium gallium zinc tin oxide (IGZTO), zinc oxide (ZnO), cadmium oxide (CdO), indium oxide (InO), zinc tin oxide (ZTO), and zinc indium tin oxide (ZITO).

For example, the first active layer ACT1 of the first driving transistor DT1 and the second active layer ACT2 of the second driving transistor DT2 may comprise different semiconductor materials.

For example, the first active layer ACT1 of the first driving transistor DT1 may include a silicon-based semiconductor material. For example, the silicon-based semiconductor material may include low-temperature polycrystalline silicon (LTPS) or the like.

The display panel 110 according to embodiments of the disclosure may further include an encapsulation layer ENCAP on a first light emitting element ED1, a second light emitting element ED2, and a third light emitting element ED3, and a touch sensor metal TSM on the encapsulation layer ENCAP.

The touch sensor metal TSM may be disposed in the normal area NA and the first optical bezel area OBA1.

Referring to FIG. 8, the first optical area OA1 may overlap the first optical electronic device 11. The first optical bezel area OBA1 may not overlap the first optical electronic device 11. In some cases, a portion of the first optical bezel area OBA1 may overlap the first optical electronic device 11.

Referring to FIG. 8, the cross-sectional structure of the normal area NA may be the same as that of the first optical bezel area OBA. However, the first pixel circuit SPC1 disposed in the first optical bezel area OBA1 to drive the first light emitting element ED1 disposed in the first optical area OA1 is not disposed in the normal area NA.

FIG. 9 is a cross-sectional view illustrating a first optical bezel area OBA1 and a first optical area OA1 of a display panel 110 according to embodiments of the disclosure. However, FIG. 9 is a cross-sectional view when the 1:2 circuit connection scheme is applied as in FIG. 6.

The cross-sectional view of FIG. 9 is basically the same as the cross-sectional view of FIG. 8. The only difference is that the cross-sectional view of FIG. 8 adopts the 1:1 circuit unit connection scheme shown in FIG. 5 while the cross-sectional view of FIG. 9 adopts the 1:2 circuit unit connection scheme shown in FIG. 6. Thus, the following description of the cross-sectional structure of FIG. 9 focuses primarily on differences from the cross-sectional structure of FIG. 8.

Referring to FIG. 9, the first light emitting element ED1 and the fourth light emitting element ED4 disposed in the first optical area OA1 may be simultaneously driven by the first driving transistor DT1 disposed in the first optical bezel area OBA1.

Therefore, as illustrated in FIG. 9, the anode extension line AEL may be further electrically connected to the fourth anode electrode AE4 different from the first anode electrode AE1. In other words, the anode extension line AEL may be electrically connected to both the first anode electrode AE1 of the first light emitting element ED1 and the fourth anode electrode AE4 of the fourth light emitting element ED4.

Referring to FIG. 9, the first emission area EA1 by the first light emitting element ED1 and the fourth emission area EA4 by the fourth light emitting element ED4 may be emission areas emitting light of the same color.

A plurality of pixel circuit units including a driving circuit for driving a plurality of light emitting elements disposed in the first optical area OA1 and a plurality of pixel circuit units including a driving circuit for driving a plurality of light emitting elements disposed in the first optical bezel area OBA1 may be disposed in the first optical bezel area OBA1.

Further, a plurality of pixel circuit units including a driving circuit for driving a plurality of light emitting elements disposed in the normal area NA may be included in the normal area NA.

Since not only the pixel circuit units for driving the light emitting elements disposed in the first optical bezel area OBA1 but also the pixel circuit units for driving the light emitting elements disposed in the first optical area OA1 should be disposed in a limited area in the first optical bezel area OBA1, the size of one pixel circuit unit disposed in the first optical bezel area OBA1 may be smaller than the size of one pixel circuit unit disposed in the normal area NA.

For example, the size of the pixel circuit unit disposed in the first optical bezel area OBA1 may be reduced by the same ratio in each of the lengths in the row direction and column direction as compared with the size of the pixel circuit unit disposed in the normal area NA.

However, since a display panel requiring a high resolution or a display panel for implementing low power consumption has an increased number of pixel circuit units or components (e.g., thin film transistors, etc.) disposed in the pixel circuit unit, it may be hard to design it so that the size of the pixel circuit unit disposed in the first optical bezel area OBA1 is smaller than the size of the pixel circuit unit disposed in the normal area NA.

In particular, when the column-wise length of the plurality of pixel circuit units disposed in the first optical bezel area OBA1 is not reduced, the area of the first optical bezel area OBA1 may be increased. In this case, the resolution of the display panel may be partially reduced.

Further, when the row-wise length of the plurality of pixel circuit units disposed in the first optical bezel area OBA1 is not reduced, it may be impossible to design signal lines (e.g., gate lines) extending in the row direction, causing the shape of the first optical bezel area OBA1 to differ from the designed shape.

Thus, at least two pixel circuit units that differ in row-wise length and column-wise length may be disposed in the first optical bezel area OBA1 of the display panel 110 according to embodiments of the disclosure.

Further, the row-wise length and column-wise direction of at least two pixel circuit units disposed in the first optical bezel area OBA1 may differ from the row-wise length and column-wise length of the pixel circuit unit disposed in the normal area NA.

As such, it is possible to allow the plurality of light emitting elements disposed in the first optical area OA1 and the first optical bezel area OBA1 to emit light without a problem even in the display panel 110 for implementing high resolution and low power consumption by adjusting the row-wise length and column-wise length of the pixel circuit unit in the first optical bezel area OBA1.

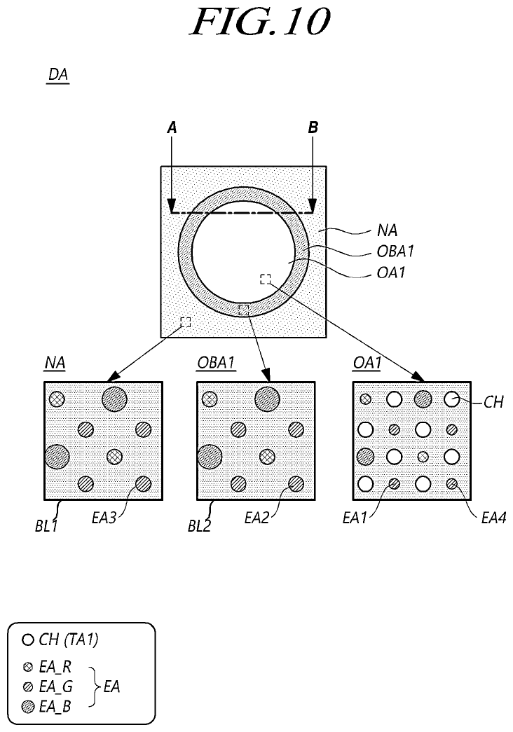

The arrangement structure of emission areas EA1, EA2, EA3, and EA4 in each of the normal area NA, first optical bezel area OBA1, and first optical area OA1 and the arrangement structure of subpixel circuit units in each of the normal area NA and the first optical bezel area OBA1 are described below with reference to FIG. 10.

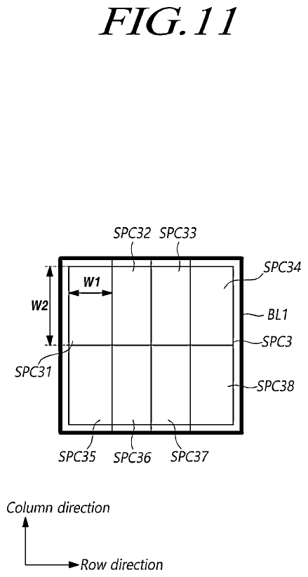

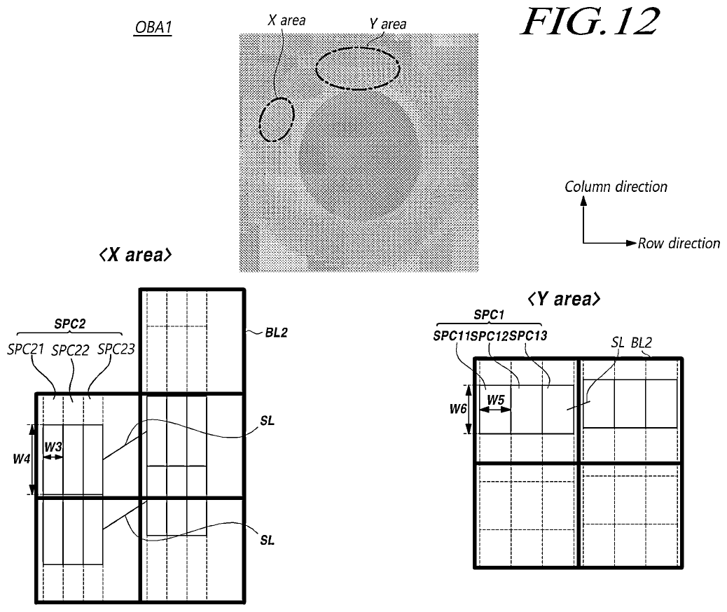

FIG. 10 is a view illustrating an arrangement of emission areas in each of a first optical area OA1, a first optical bezel area OBA1, and a normal area NA in a display panel according to embodiments of the disclosure. FIG. 11 is a view illustrating a structure in which subpixel circuit units are arranged in one block in a normal area according to embodiments of the disclosure. FIG. 12 is a view illustrating a structure in which subpixel circuit units are arranged in one block in each an X area and a Y area of a first optical bezel area according to embodiments of the disclosure.

First, referring to FIG. 10, the display panel 110 according to embodiments may include the first optical area OA1, the first optical bezel area OBA1 surrounding the first optical area OA1, and the normal area NA surrounding the optical bezel area OBA1.

A plurality of emission areas spaced apart from each other may be disposed in each of the first optical area OA1, the first optical bezel area OBA1, and the normal area NA.

Referring to FIG. 10, a plurality of blocks BL including a plurality of emission areas may be included in the first optical bezel area OBA1 and the normal area NA.

For example, as illustrated in FIG. 10, one block BL may include eight emission areas spaced apart from each other. However, the number of emission areas included in one block BL shown in FIG. 10 is merely an example, and a configuration in which one or more emission areas are disposed in each block BL suffices.

The size of the block BL of the first optical bezel area OBA1 and the size of the block BL of the normal area NA may be the same or different. For convenience of description, the following description focuses primarily on a structure in which the size of the block BL of the first optical bezel area OBA1 and the size of the block BL of the normal area NA are the same.

Hereinafter, the block included in the normal area NA may be referred to as a first block BL1, and the block included in the first optical bezel area OBA1 may be referred to as a second block BL2.

In the first optical bezel area OBA1 and the normal area NA, each block BL may be an area where at least one pixel circuit unit is disposed and at least one emission area is disposed.

Specifically, the total number of subpixel circuit units included in the first block BL1 of the normal area NA matches the total number of third emission areas EA3 included in the first block BL1 of the normal area NA.

The total number of subpixel circuit units included in the second block BL2 of the first optical bezel area OBA1 may be different from the total number of second emission areas EA2 disposed in the first optical bezel area OBA1 due to the first optical bezel area OBA1 including subpixel circuit units for driving emission areas included in the optical area OA1.

Referring to FIGS. 10 and 11, the first block BL1 included in the normal area NA may include eight third emission areas EA3 and eight subpixel circuit units SPC31, SPC32, SPC33, SPC34, SPC35, SPC36, SPC37, and SPC38.

One subpixel circuit unit of the normal area NA may drive the light emitting element ED3 disposed in one third emission area EA3.

In other words, as illustrated in FIG. 10, because eight third light emitting areas EA3 may be disposed in one first block BL1, as illustrated in FIG. 11, one first block BL1 of the normal area NA may include eight subpixel circuit units SPC31, SPC32, SPC33, SPC34, SPC35, SPC36, SPC37, and SPC38 for driving the eight light emitting elements ED3 disposed in each of the eight third light emitting areas EA3.

As illustrated in FIG. 11, in the first block BL1 of the normal area NA, a total of eight subpixel circuit units SPC31, SPC32, SPC33, SPC34, SPC35, SPC36, SPC37, and SPC38 may be arranged in two rows each row including four subpixel circuit units.

The area of the eight subpixel circuit units SPC31, SPC32, SPC33, SPC34, SPC35, SPC36, SPC37, and SPC38 arranged as described above may correspond to the area of one first block BL1.

Further, each of the plurality of subpixel circuit units SPC31, SPC32, SPC33, SPC34, SPC35, SPC36, SPC37, and SPC38 disposed in the normal area NA may have the same size as the other subpixel circuit units in the normal area NA.

Here, the size or the dimensions of the subpixel circuit units may be defined by the row-wise width (e.g., length) and the column-wise width (e.g., length) in the planar structure (e.g., plan view of the display device). That is, the dimensions of a subpixel circuit unit are defined by a length (or width) in a first direction (e.g., row direction) and a length (or width) in a second direction (e.g., column direction) in a plan view of the display device.

The row-wise width of the subpixel circuit units may mean the shortest length between the first signal line extending in the column direction and the first signal line disposed in another subpixel circuit unit adjacent thereto. Also, the row-wise width of the subpixel circuit units may mean the shortest length (the shortest length in the row direction) between the first storage capacitor electrode and the first storage capacitor electrode disposed in another subpixel circuit unit adjacent thereto.

The column-wise width of the subpixel circuit units may mean the shortest length between the second signal line extending in the row direction and the second signal line disposed in another subpixel circuit unit adjacent thereto. Also, the column-wise width of the subpixel circuit units may mean the shortest length (the shortest length in the column direction) between the first storage capacitor electrode and the first storage capacitor electrode disposed in another subpixel circuit unit adjacent thereto.

The row-wise width of the subpixel circuit unit may mean a pitch in the row direction, and the column-wise width may mean a pitch in the column direction.

Referring to FIGS. 10 to 12, the subpixel circuit units SPC21, SPC22, SPC23, SPC11, SPC12, and SPC13 having sizes different from the subpixel circuit units SPC31, SPC32, SPC33, SPC34, SPC35, SPC36, SPC37, and SPC38 of the normal area NA may be disposed in the X and Y areas of the first optical bezel area OBA1.

The X area of the first optical bezel area OBA1 may be an area having the lowest density of the subpixel circuit units in the first optical bezel area OBA1, and the Y area may be an area having the highest density of the subpixel circuit units in the first optical bezel area OBA1.

The first optical bezel area OBA1 may include at least one X area and at least one Y area.

At least one of the row-wise length W3 (e.g., length in a first direction) and the column-wise length W4 (e.g., length in a second direction) of the subpixel circuit units SPC21, SPC22, and SPC23 of the X area of the first optical bezel area OBA1 may be different from at least one of the row-wise length W1 and the column-wise length W2 of the subpixel circuit units SPC31, SPC32, SPC33, SPC34, SPC35, SPC36, SPC37, and SPC38 of the normal area NA.

For example, the row-wise length W3 of the subpixel circuit units SPC21, SPC22, and SPC23 positioned in the X area of the first optical bezel area OBA1 may be less than the row-wise length W1 of the subpixel circuit units SPC31, SPC32, SPC33, SPC34, SPC35, SPC36, SPC37, and SPC38 of the normal area NA.

Further, the column-wise length W4 of the subpixel circuit units SPC21, SPC22, and SPC23 positioned in the X area of the first optical bezel area OBA1 may be greater than the column-wise length W2 of the subpixel circuit units SPC31, SPC32, SPC33, SPC34, SPC35, SPC36, SPC37, and SPC38 of the normal area NA.

At least one of the row-wise length W5 and the column-wise length W6 of the subpixel circuit units SPC11, SPC12, and SPC13 of the Y area of the first optical bezel area OBA1 may be different from at least one of the row-wise length W1 and the column-wise length W2 of the subpixel circuit units SPC31, SPC32, SPC33, SPC34, SPC35, SPC36, SPC37, and SPC38 of the normal area NA.

For example, the row-wise length W5 of the subpixel circuit units SPC11, SPC12, and SPC13 positioned in the Y area of the first optical bezel area OBA1 may be greater than the row-wise length W1 of the subpixel circuit units SPC31, SPC32, SPC33, SPC34, SPC35, SPC36, SPC37, and SPC38 of the normal area NA.

Further, the column-wise length W6 of the subpixel circuit units SPC11, SPC12, and SPC13 positioned in the Y area of the first optical bezel area OBA1 may be less than the column-wise length W2 of the subpixel circuit units SPC31, SPC32, SPC33, SPC34, SPC35, SPC36, SPC37, and SPC38 of the normal area NA.

Accordingly, referring to FIG. 11, in the normal area NA, the size of one block in which the eight third light emitting areas EA3 are disposed may correspond to the size of the eight subpixel circuit units SPC31, SPC32, SPC33, SPC34, SPC35, SPC36, SPC37, and SPC38.

Referring to FIG. 12, at least one of the row-wise length W3 and the column-wise length W4 of the subpixel circuit units SPC21, SPC22, and SPC23 disposed in the X area of the first optical bezel area OBA1 may be different from at least one of the row-wise length W5 and the column-wise length W6 of the subpixel circuit units SPC11, SPC12, and SPC13 disposed in the Y area of the first optical bezel area OBA1.

For example, the row-wise length W3 of the subpixel circuit units SPC21, SPC22, and SPC23 disposed in the X area of the first optical bezel area OBA1 may be less than the row-wise length W5 of the subpixel circuit units SPC11, SPC12, and SPC13 disposed in the Y area of the first optical bezel area OBA1.

Further, the column-wise length W4 of the subpixel circuit units SPC21, SPC22, and SPC23 positioned in the Y area of the first optical bezel area OBA1 may be greater than the column-wise length W6 of the subpixel circuit units SPC11, SPC12, and SPC13 disposed in the Y area of the first optical bezel area OBA1.

As described above, in the first optical bezel area OBA1, the size of one subpixel circuit unit SPC21, SPC22, SPC23, SPC24, SPC25, and SPC26 may vary depending on the position thereof.

Further, as the position of the first optical bezel area OBA1 is moved from the X area to the Y area, the row-wise length of the subpixel circuit units may be increased.

As the position of the first optical bezel area OBA1 is moved from the X area to the Y area, the column-wise length of the subpixel circuit units may be decreased

Referring to FIG. 12, in at least a partial area of the first optical bezel area OBA1, the size of one second block BL2 may be larger than the size of a plurality of subpixel circuit units disposed in the corresponding second block BL2.

For example, in the X area of the first optical bezel area OBA1 illustrated in FIG. 12, the size of one second block BL2 may be larger than the size of the plurality of subpixel circuit units SPC21, SPC22, and SPC23 disposed in the corresponding second block BL2. Accordingly, the X area of the first optical bezel area OBA1 may include an area in which the plurality of subpixel circuit units SPC21, SPC22, and SPC23 are not disposed in the at least one second block BL2.

As such, in the area where no subpixel circuit unit is disposed in at least one second block BL2 of the X area of the first optical bezel area OBA1, at least one signal line SL may be disposed.

Specifically, referring to FIG. 12, the three subpixel circuit units SPC21, SPC22, and SPC23 arranged in the row direction in the X area of the first optical bezel area OBA1 may constitute one second pixel circuit SPC2.

As illustrated in FIGS. 10 and 12, when eight light emitting areas are disposed in one block of the first optical bezel area OBA1, each of the subpixel circuit units SPC21, SPC22, and SPC23 may drive light emitting elements disposed in at least two light emitting areas. For example, the SPC21 may drive light emitting elements disposed in two red light emitting areas, the SPC22 may drive light emitting elements disposed in four green light emitting areas, and the SPC23 may drive light emitting elements disposed in two blue light emitting areas.

Referring to FIG. 12, in the X area of the first optical bezel area OBA1, at least one second pixel circuit SPC2 may be disposed to be spaced apart from the second pixel circuit SPC2 disposed in another adjacent block.

The second pixel circuits SPC2 may be electrically connected through a signal line SL (e.g., a gate line GL) provided in a separation space between the second pixel circuits SPC2.

In the area where no subpixel circuit unit is disposed in at least one second block BL2 of the X area of the first optical bezel area OBA1, at least one signal line SL may be disposed.

Referring to FIG. 12, in the X area of the first optical bezel area OBA1, the signal line SL electrically connecting one second pixel circuit SPC2 and another adjacent second pixel circuit SPC2 may extend at an angle of more than 0° and less than 90° with respect to the row direction.

In the Y area of the first optical bezel area OBA1, the three subpixel circuit units SPC11, SPC12, and SPC13 arranged side by side in the row direction may constitute one first pixel circuit SPC1.

As illustrated in FIG. 12, since the subpixel circuit units SPC11, SPC12, and SPC13 formed to be longer in the row direction in the Y area than the X area are disposed in the Y area of the first optical bezel area OBA1, the distance between the first pixel circuit SPC1 disposed in one second block BL2 of the Y area and the first pixel circuit SPC1 disposed in another second block BL2 adjacent thereto may be shorter than the distance between the second pixel circuit SPC2 disposed in one second block BL2 of the X area and the second pixel circuit SPC2 disposed in another second block BL2 adjacent thereto.

Also, referring to FIG. 12, in the Y area of the first optical bezel area OBA1, a signal line SL electrically connecting one first pixel circuit SPC1 and another adjacent first pixel circuit SPC1 may extend.

The angle from the row direction of the signal line SL disposed in the Y area of the first optical bezel area OBA1 may be smaller than the angle from the row direction of the signal line SL disposed in the X area of the first optical bezel area OBA1.

Referring to FIG. 12, the X area of the first optical bezel area OBA1 is an area from 0° to 90° with respect to the row direction (or column direction), and an area in which the signal line SL connected in the row direction may be positioned should be provided while the area in the column direction may have a larger design space than the area in the row direction. Thus, in the X area, the signal line SL may extend in a shape (e.g., a diagonal line shape) that is inclined to have an angle from 0° to 90° with respect to the row direction.

In other words, since the X area of the first optical bezel area OBA1 has a higher degree of freedom in the column direction than the Y area, the degree of freedom in the column length of the subpixel circuit units SPC21, SPC22, and SPC23 of the X area may also be higher.

Accordingly, the column-wise length W4 of the subpixel circuit units SPC21, SPC22, and SPC23 disposed in the X area may be longer than the column-wise length W6 of the subpixel circuit units SPC11, SPC12, and SPC13 disposed in the Y area.

Since the Y area of the first optical bezel area OBA1 has a narrower separate area for the signal line SL extending in the row direction than the X area, the Y area may have a higher degree of freedom in the row direction than the X area, and thus the subpixel circuit units SPC11, SPC12, and SPC13 of the Y area may have a higher degree of freedom in the row direction.

Accordingly, the row-wise length W5 of the subpixel circuit units SPC11, SPC12, and SPC13 disposed in the Y area may be longer than the row-wise length W3 of the subpixel circuit units SPC21, SPC22, and SPC23 disposed in the X area.

However, the Y area of the first optical bezel area OBA1 is a portion having a structure in which the anode electrode AE extends to the light emitting area disposed in the first optical area OA1 in the column direction through the subpixel circuit unit of the Y area and has the highest density of the subpixel circuit units SPC11, SPC12, and SPC13 amongst the different areas in the first optical bezel area OBA1, and as the area occupied by the subpixel circuit units in the column direction increases, the size of the first optical bezel area OBA1 may increase.

Accordingly, there may be a probability that an area in which the resolution is partially lowered in the display panel 110 increases. Therefore, in order to prevent the column-wise length of the Y area of the first optical bezel area OBA1 from increasing, the column-wise length W6 of the subpixel circuit units SPC11, SPC12, and SPC13 disposed in the Y area may be shorter than the column-wise length W4 of the subpixel circuit units SPC21, SPC22, and SPC23 disposed in the X area.

In FIG. 12, a structure in which three subpixel circuit units constitute one pixel circuit in the first optical bezel area OBA1 has been mainly described, but embodiments of the disclosure are not limited thereto.

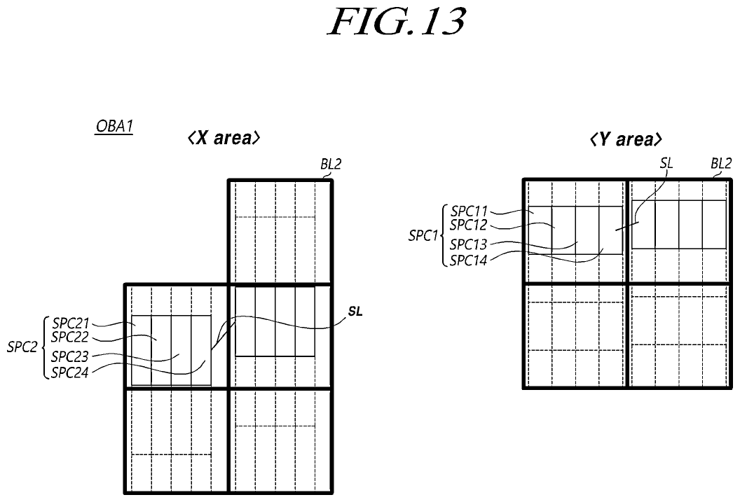

FIG. 13 is a view schematically illustrating a structure in which a plurality of subpixel circuit units are disposed in a first optical bezel area.

Referring to FIG. 13, the four subpixel circuit units SPC21, SPC22, SPC23, and SPC24 arranged in the row direction in the X area of the first optical bezel area OBA1 may constitute one second pixel circuit SPC2.

The second pixel circuits SPC2 may be electrically connected through a signal line SL provided in a separation space between the second pixel circuits SPC2.

Referring to FIG. 13, the four subpixel circuit units SPC11, SPC12, SPC13, and SPC14 arranged side by side in the row direction in the Y area of the first optical bezel area OBA1 may constitute one first pixel circuit SPC1.

In the Y area of the first optical bezel area OBA1, a signal line SL electrically connecting one first pixel circuit SPC1 and another adjacent first pixel circuit SPC1 may extend in the row direction.

As the first optical bezel area OBA1 moves from the X area to the Y area, the length of the signal line SL between one second pixel circuit SPC2 and another adjacent second pixel circuit SPC2 may decrease.

Referring to FIG. 13, in the X area of the first optical bezel area OBA1, the signal line SL electrically connecting one second pixel circuit SPC2 and another adjacent second pixel circuit SPC2 may extend at an angle of more than 0° and less than 90° with respect to the row direction.

As illustrated in FIG. 13, when eight light emitting areas are disposed in one second block BL2 and four subpixel circuit units constitute one pixel circuit, each subpixel circuit unit may drive the light emitting elements disposed in two light emitting areas.

As described above, in the display panel 110 according to the embodiments of the disclosure, the pixel circuit disposed in the first optical bezel area OBA1 may include a plurality of subpixel circuit units to efficiently drive the light emitting elements disposed in the first optical bezel area OBA1 and the first optical area OA1.

The structure of the subpixel circuit unit disposed in the first optical bezel area OBA1 is described below in detail.

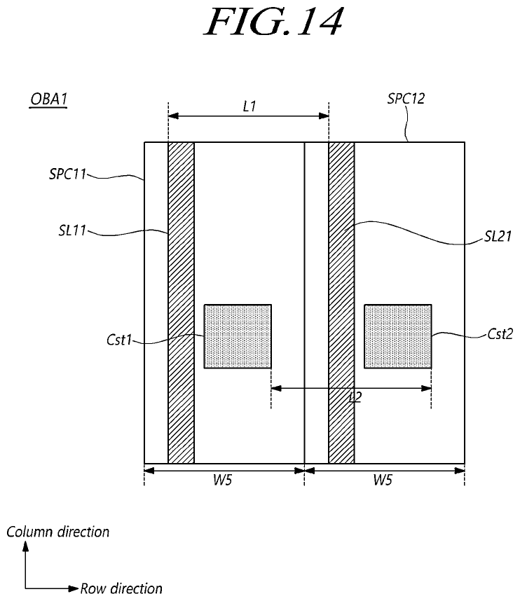

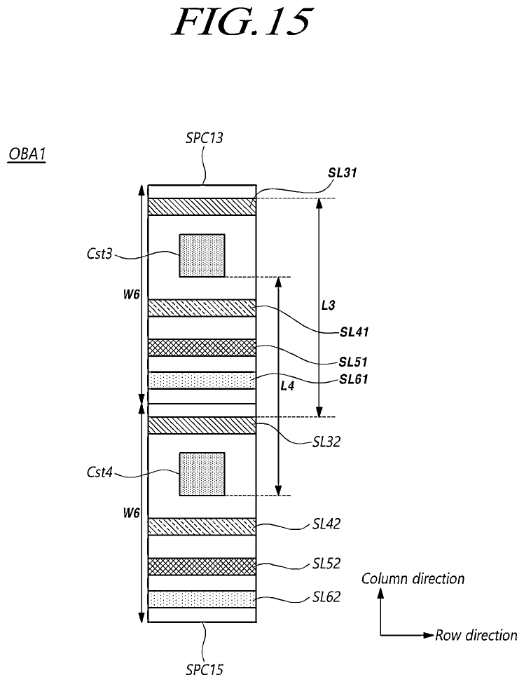

FIGS. 14 and 15 are views schematically illustrating a structure of a subpixel circuit unit disposed in a first optical bezel area.

Referring to FIGS. 14 and 15, a plurality of subpixel circuits may be disposed in the first optical bezel area OBA1, and a first subpixel circuit unit SPC11, a second subpixel circuit unit SPC12, a third subpixel circuit unit SPC13, and a fifth subpixel circuit unit SPC15 may be included.

Referring to FIG. 14, the plurality of subpixel circuit units SPC11 and SPC12 may be arranged in a row direction, or referring to FIG. 15, the plurality of subpixel circuit units SPC13 and SPC15 may also be arranged in a column direction.

Referring to FIGS. 14 and 15, each of the plurality of subpixel circuit units SPC11, SPC12, SPC13, and SPC15 may include an area defined by two signal lines SL11 and SL21 among a plurality of signal lines extending in the column direction and two signal lines SL31 and SL32, SL41 and SL42, SL51 and SL52, or SL61 and SL62 among a plurality of signal lines extending in the row direction.

For example, each of the plurality of subpixel circuit units SPC11, SPC12, SPC13, and SPC15 may include an area defined by two data lines SL11 and SL21 extending in the column direction and spaced apart from each other and two gate lines SL31 and SL32, SL41 and SL42, SL51 and SL52, or SL61 and SL62 extending in the row direction and spaced apart from each other.

Referring to FIG. 14, the row-wise lengths W5 of the plurality of subpixel circuit units disposed in the Y area of the first optical bezel area OBA1, including the first subpixel circuit unit SPC11 and the second subpixel circuit unit SPC12, may be the same (also shown in FIG. 12).

The row-wise distance L1 between the first signal line SL11 extending in the column direction in the Y area of the first optical bezel area OBA1 and the second signal line SL21 adjacent thereto may be the row-wise length W5 of the plurality of subpixel circuit units disposed in the Y area (L1=W5). The row-wise length W5 of the plurality of subpixel circuit units may mean the shortest pitch in the row direction between the first signal line SL11 and the second signal line SL21 adjacent thereto.

Here, the first signal line SL11 may be a signal line supplying a first signal (e.g., a data signal, a reference voltage, or a power supply voltage) to the first subpixel circuit unit SPC11, and the second signal line SL21 may be a signal line supplying the first signal (e.g., the same signal as the signal supplied through SL11) to the second subpixel circuit unit SPC12. In other words, the first and second signal lines SL21 may be any one of a data line, a reference voltage line, or a power supply voltage line.

Referring to FIGS. 14 and 15, at least one storage capacitor Cst1, Cst2, Cst3, or Cst4 may be disposed in each of the plurality of subpixel circuit units SPC11, SPC12, SPC13, and SPC15 disposed in the first optical bezel area OBA1.

Each of the storage capacitors Cst1, Cst2, Cst3, and Cst4 may include at least two storage capacitor electrodes.

Referring to FIG. 14, the row-wise distance L2 between a side (e.g., right side) of the first storage capacitor electrode of the first storage capacitor Cst1 disposed in the first subpixel circuit unit SPC11 and a side (e.g., right side) of the second storage capacitor electrode of the second storage capacitor Cst2 disposed in the second subpixel circuit unit SPC12 may be the row-wise length W5 of the plurality of subpixel circuit units disposed in the Y area (L2=W5). The row-wise length W5 of the plurality of subpixel circuit units may mean the row-wise shortest pitch between the first storage capacitor electrode of the first storage capacitor Cst1 disposed in the first subpixel circuit unit SPC11 and the second storage capacitor electrode of the second storage capacitor Cst2 disposed in the second subpixel circuit unit SPC12.

Here, the first storage capacitor electrode of the first storage capacitor Cst1 and the second storage capacitor electrode of the second storage capacitor Cst2 disposed in the second subpixel circuit unit SPC12 may be electrodes disposed on the same layer and including the same material.

Referring to FIG. 15, the column-wise lengths W6 of the plurality of subpixel circuit units disposed in the Y area of the first optical bezel area OBA1, including the third subpixel circuit unit SPC13 and the fifth subpixel circuit unit SPC15, may be the same (also shown in FIG. 12).

The column-wise distance L3 between the 3-1th signal line SL31 extending in the row direction in the Y area of the first optical bezel area OBA1 and the 3-2th signal line SL32 may be the column-wise length W6 of the plurality of subpixel circuit units disposed in the Y area (L3=W6). The column-wise length W6 of the plurality of subpixel circuit units may mean the shortest pitch in the column direction between the 3-1th signal line SL31 and the 3-2th signal line SL32.

Here, the 3-1th signal line SL31 may be a signal line supplying a second signal (e.g., a gate signal) to the third subpixel circuit unit SPC31, and the 3-2th signal line SL32 may be a signal line supplying a second signal (e.g., the same signal as the signal supplied through SL31) to the fifth subpixel circuit unit SPC51.

Further, referring to FIG. 15, the column-wise distance L4 between the third storage capacitor electrode of the third storage capacitor Cst3 disposed in the third subpixel circuit unit SPC31 and the fourth storage capacitor electrode of the fourth storage capacitor Cst4 disposed in the fifth subpixel circuit unit SPC51 may be the column-wise length W6 of the plurality of subpixel circuit units disposed in the Y area (L4=W6). The column-wise length W6 of the plurality of subpixel circuit units may mean the column-wise shortest pitch between the third storage capacitor electrode of the third storage capacitor Cst3 disposed in the third subpixel circuit unit SPC31 and the fourth storage capacitor electrode of the fourth storage capacitor Cst4 disposed in the fifth subpixel circuit unit SPC51.

Here, the third storage capacitor electrode of the third storage capacitor Cst3 and the fourth storage capacitor electrode of the fourth storage capacitor Cst4 may be electrodes disposed on the same layer and including the same material.

In FIGS. 14 and 15, the subpixel circuit units SPC11, SPC12, SPC13, and SPC15 disposed in the Y area of the first optical bezel area OBA1 have been described as examples, but the row-wise length and the column-wise length of the subpixel circuit units disposed in the first optical bezel area OBA1 of the display panel 110 according to embodiments of the disclosure may be equally applied.

Referring to FIG. 15, the column-wise distance L3 between the 3-1th signal line SL31 and the 3-2th signal line SL32 may be the same as the column-wise distance between the 4-1th signal line SL41 and the 4-2th signal line SL42, the column-wise distance between the 5-1th signal line SL51 and the 5-2th signal line SL52, and the column-wise distance between the 6-1th signal line SL61 and the 6-2th signal line SL62.

Accordingly, the column-wise distance L3 between the 3-1th signal line SL31 and the 3-2th signal line SL32 may be the same as the column-wise distance between the 4-1th signal line SL41 and the 4-2th signal line SL42, the column-wise distance between the 5-1th signal line SL51 and the 5-2th signal line SL52, and the column-wise distance between the 6-1th signal line SL61 and the 6-2th signal line SL62 may be the same as the column-wise length W6 of the plurality of subpixel circuit units disposed in the Y area.

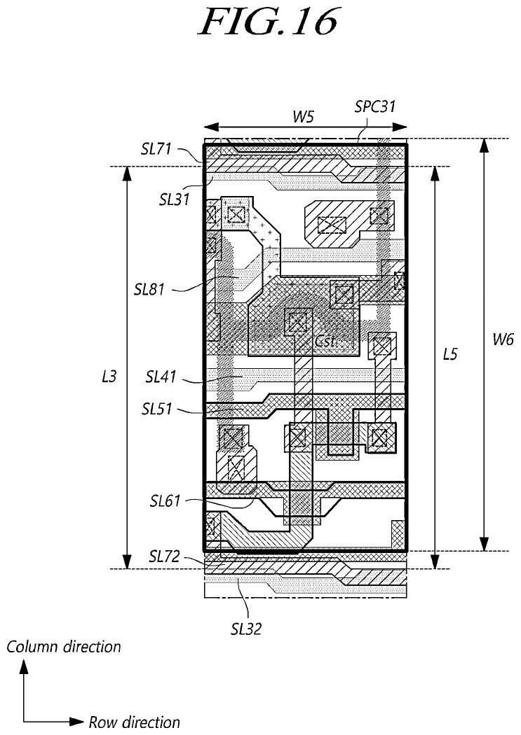

Further, components having the same distance as the column-wise length of one subpixel circuit unit of the first optical bezel area OBA1 will be further described with reference to FIG. 16.

FIG. 16 is a plan view illustrating a structure of a subpixel circuit unit disposed in a first optical bezel area according to one embodiment.

Referring to FIG. 16, the column-wise distance L5 between the 7-1th signal line SL71 disposed in one subpixel circuit unit and extending in the row direction and the 7-2th signal line SL72 disposed in another subpixel circuit unit adjacent in the column direction may be the same as the column-wise length W6 of the plurality of subpixel circuit units of the first optical bezel area OBA1.

Here, the 7-1 signal line SL71 may be a signal line (initialization voltage line) for supplying (e.g., supplying initialization voltage) the third signal to the third subpixel circuit unit SPC31, and the 7-2 signal line SL72 may be a signal line for supplying the third signal (e.g., the same signal as the signal supplied through SL71) to the fifth subpixel circuit unit SP51.

Further, although not illustrated in FIG. 16, the column-wise distance between the 8-1th signal line SL81 extending in the row direction in the first optical bezel area OBA1 and the 8-2th signal line (not illustrated) disposed in another subpixel circuit unit adjacent thereto in the column direction may also be the same as the column-wise length W6 of the plurality of subpixel circuit units of the first optical bezel area OBA1.

Here, the 8-1 signal line SL81 and the 8-2 signal line may be lines (emission control lines) to which an emission control signal is supplied.

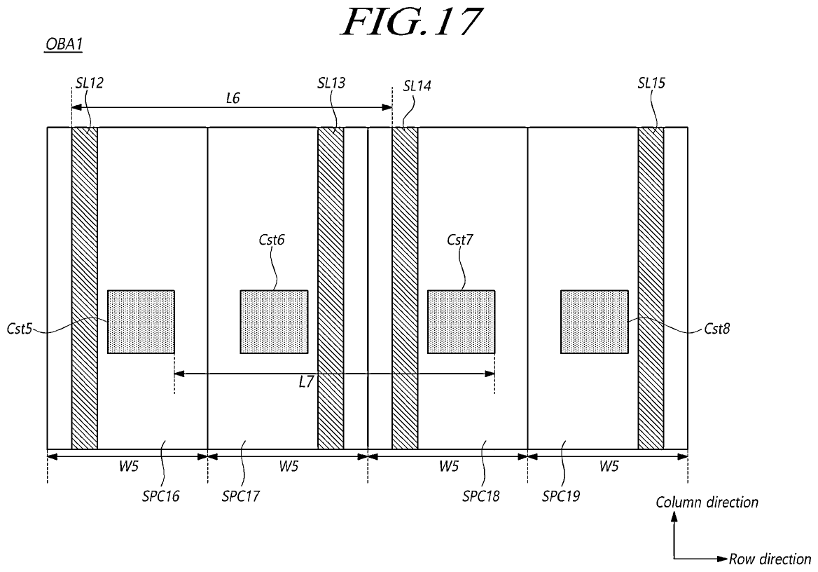

FIG. 17 is a view schematically illustrating a plurality of subpixel circuit units disposed in a first optical bezel area and a signal line and a storage capacitor disposed in each subpixel circuit unit according to one embodiment.

Referring to FIG. 17, the plurality of subpixel circuit units SPC16, SPC17, SPC18, and SPC19 may be arranged in the row direction in the first optical bezel area OBA1.

For example, along the row direction, the seventh subpixel circuit unit SPC17 may be disposed on one side of the sixth subpixel circuit unit SPC16, the eighth subpixel circuit unit SPC18 may be disposed on one side of the seventh subpixel circuit unit SPC17, and the ninth subpixel circuit unit SPC19 may be disposed on one side of the eighth subpixel circuit unit SPC18.

Here, the sixth subpixel circuit unit SPC16 may have the same structure as the eighth subpixel circuit unit SPC18, and the seventh subpixel circuit unit SPC17 may have the same structure as the ninth subpixel circuit unit SPC19.

In other words, the sixth subpixel circuit unit SPC16 and the seventh subpixel circuit unit SPC17 may be linearly symmetrical with respect to the boundary between the sixth subpixel circuit unit SPC16 and the seventh subpixel circuit unit SPC17. Further, the eighth subpixel circuit unit SPC18 and the ninth subpixel circuit unit SPC19 may be linearly symmetrical with respect to the boundary between the eighth subpixel circuit unit SPC18 and the ninth subpixel circuit unit SPC19.

The sixth to ninth subpixel circuit units SPC16, SPC17, SPC18, and SPC19 may have signal lines SL12, SL13, SL14, and SL15, respectively, supplied with a first signal (e.g., a data signal) and extending in the column direction.

Further, storage capacitors Cst5, Cst6, Cst7, and Cst8 may be disposed in the sixth to ninth subpixel circuit units SPC16, SPC17, SPC18, and SPC19, respectively.

In this structure, the row-wise length W5 of each of the sixth to ninth subpixel circuit units SPC16, SPC17, SPC18, and SPC19 may be a length corresponding to ½ of the distance L6 between the signal line SL12 disposed in the sixth subpixel circuit unit SPC16 and the signal line SL14 disposed in the eighth subpixel circuit unit SPC18.

Further, the row-wise length W5 of each of the sixth to ninth subpixel circuit units SPC16, SPC17, SPC18, and SPC19 may be a length corresponding to ½ of the distance between the signal line SL13 disposed in the seventh subpixel circuit unit SPC17 and the signal line SL15 disposed in the ninth subpixel circuit unit SPC19.

Further, the row-wise length W5 of each of the sixth to ninth subpixel circuit units SPC16, SPC17, SPC18, and SPC19 may be a length corresponding to ½ of the row-wise distance L7 between a side (e.g., a right side) of the fifth storage capacitor electrode of the fifth storage capacitor Cst5 disposed in the sixth subpixel circuit unit SPC16 and a side (e.g., a right side) of the seventh storage capacitor electrode of the seventh storage capacitor Cst7 disposed in the eighth subpixel circuit unit SPC18.

The fifth storage capacitor electrode and the seventh storage capacitor electrode may be storage capacitor electrodes disposed on the same layer and including the same material.

Further, the row-wise length W5 of each of the sixth to ninth subpixel circuit units SPC16, SPC17, SPC18, and SPC19 may be a length corresponding to ½ of the row-wise distance between a side (e.g., right side) of the sixth storage capacitor electrode of the sixth storage capacitor Cst6 disposed in the seventh subpixel circuit unit SPC17 and a side (e.g., right side) of the eighth storage capacitor electrode of the eighth storage capacitor Cst8 disposed in the ninth subpixel circuit unit SPC19.

The sixth storage capacitor electrode and the eighth storage capacitor electrode may be storage capacitor electrodes disposed on the same layer and including the same material.

The second optical area OA2 according to embodiments of the disclosure is described below.

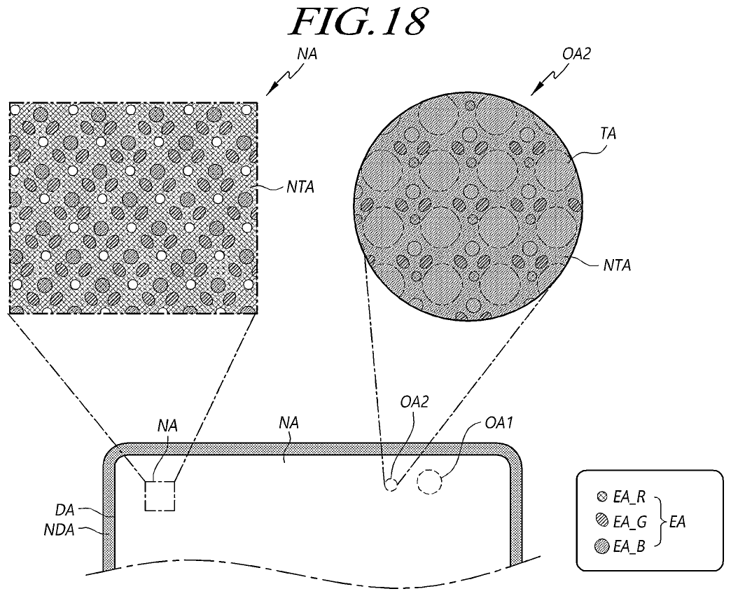

FIG. 18 is a view schematically illustrating a normal area NA and a second optical area OA2 in a display panel 110 according to embodiments of the disclosure.

Referring to FIG. 18, the display area DA of the display panel 110 may further include a second optical area OA2 as well as the normal area NA and the first optical area OA1.

The first optical area OA1 may be an area overlapping the first optical electronic device 11, and the second optical area OA2 may be an area overlapping the second optical electronic device 12.

The first optical electronic device 11 and the second optical electronic device 12 may be devices having different wavelengths of light required or used for operation.

For example, one of the first optical electronic device 11 and the second optical electronic device 12 is a camera using visible light, and the other is a sensor using light (e.g., infrared light or ultraviolet light) of a wavelength band different from visible light.

For example, the first optical electronic device 11 may be a camera, and the second optical electronic device 12 may be an infrared sensor.

Referring to FIG. 18, the second optical area OA2 may include a non-transmissive area NTA including a plurality of emission areas EA, and may further include a transmissive area TA.

As illustrated in FIG. 18, the second optical area OA2 may be designed to be the same as the first optical area OA1. However, the first optical area OA1 and the second optical area OA2 may differ in at least one of the arrangement of subpixels, positions of the subpixels, the number of subpixels per unit area, emission area of the subpixel, and transmittance.

According to embodiments of the disclosure, there may be provided a display panel and a display device having a light transmission structure in which an optical electronic device may normally receive light (e.g., visible light, infrared light, or ultraviolet light) without exposing the optical electronic device through the front surface of the display device.

According to embodiments of the disclosure, it is possible to further enhance the transmittance of the optical area by disposing only light emitting elements in the transmittable optical area while disposing pixel circuits for driving the light emitting elements in the optical area in an outer area (e.g., optical bezel area or normal area) of the optical area.

According to embodiments of the disclosure, it is possible to further enhance the transmittance of the optical area by connecting the light emitting element disposed in the transmittable optical area to the pixel circuit (transistor included in the pixel circuit) disposed in the outer area (e.g., optical bezel area or normal area) of the optical area through an anode extension line formed of a transparent material.

There may be provided a display panel and a display device capable of preventing an increase in the optical bezel area or a change of the shape of the optical bezel area to differ from the designed shape by adjusting the size of the subpixel circuit unit disposed in the optical bezel area surrounding the optical area even in a display panel for implementing low power consumption or a display panel requiring a high resolution.

The above description has been presented to enable any person skilled in the art to make and use the technical idea of the disclosure, and has been provided in the context of a particular application and its requirements. Various modifications, additions and substitutions to the described embodiments will be readily apparent to those skilled in the art, and the general principles defined herein may be applied to other embodiments and applications without departing from the spirit and scope of the disclosure. The above description and the accompanying drawings provide an example of the technical idea of the disclosure for illustrative purposes only. That is, the disclosed embodiments are intended to illustrate the scope of the technical idea of the disclosure.

What is claimed:

1. A display device comprising:
a light transmittable optical area included in a display area of the display device, the light transmittable optical area configured to display an image;
a normal area included in the display area, the normal area around the light transmittable optical area;
an optical bezel area included in the display area, the optical bezel area between the light transmittable optical area and the normal area;
a plurality of first subpixel circuit units and a plurality of second subpixel circuit units in the optical bezel area, the plurality of first subpixel circuit units including a first subpixel circuit unit and the plurality of second subpixel circuit units including a second subpixel circuit unit; and
a plurality of third subpixel circuit units in the normal area, the plurality of third subpixel circuit units including a third subpixel circuit unit,
wherein at least one of a length in a first direction and a length in a second direction of the first subpixel circuit unit and at least one of a length in the first direction and a length in the second direction of the second subpixel circuit unit is respectively different from a length in the first direction and a length in the second direction of the third subpixel circuit unit.

2. The display device of claim 1, wherein a thin film transistor is in the optical bezel area and the light transmittable optical area lacks a thin film transistor, and wherein an anode electrode of a light emitting element in the light transmittable optical area is electrically connected to a subpixel circuit unit from the plurality of first subpixel circuit units or the plurality of second subpixel circuit units in the optical bezel area.

3. The display device of claim 1, wherein the optical bezel area includes a X area and a Y area that is different from the X area, and the plurality of first subpixel circuit units are in the Y area and the plurality of second subpixel circuit units are in the X area, and a density of the plurality of second subpixel circuit units in the X area is less than a density of the plurality of first subpixel circuit units in the Y area.

4. The display device of claim 3, wherein at least one of the length in the first direction and the length in the second direction of the first subpixel circuit unit is respectively different from the length in the first direction and the length in the second direction of the second subpixel circuit unit.

5. The display device of claim 4, wherein the length in the first direction of the first subpixel circuit unit is greater than the length in the first direction of the second subpixel circuit unit, and the length in the second direction of the first subpixel circuit unit is less than the length in the second direction of the second subpixel circuit unit.

6. The display device of claim 4, wherein the length in the first direction of the first subpixel circuit unit becomes longer from the X area to the Y area, and the length in the second direction becomes shorter.

7. The display device of claim 3, wherein a distance in the first direction between the first subpixel circuit unit and another first pixel circuit unit that is adjacent to the first subpixel circuit unit is less than a distance in the first direction between the second subpixel circuit unit and another second subpixel circuit unit that is adjacent to the second subpixel circuit unit.

8. The display device of claim 7, wherein the X area includes at least one first signal line between the second subpixel circuit unit and the other second subpixel circuit unit adjacent thereto, and the at least one first signal line extends at an angle greater than 0° and less than 90° with respect to the first direction.

9. The display device of claim 8, wherein the Y area includes at least one second signal line between the first subpixel circuit unit and the other first subpixel circuit unit, and
an angle between the second signal line and the first direction is less than the angle between the first signal line and the first direction.

10. The display device of claim 1, wherein the length in the first direction of each of the first subpixel circuit unit, the second subpixel circuit unit, and the third subpixel circuit unit is a minimum pitch in the first direction between a corresponding third signal line in each of the first subpixel circuit unit, the second subpixel circuit unit, and the third subpixel circuit unit and a corresponding third signal line in each of another first subpixel circuit unit from the plurality of first subpixel circuit units, another second subpixel circuit unit from the plurality of second subpixel circuit units, and another third subpixel circuit unit from the plurality of third subpixel circuit units adjacent thereto in the first direction, and
wherein the corresponding third signal line extends in the second direction.

11. The display device of claim 1, wherein the length in the second direction of each of the first subpixel circuit unit, the second subpixel circuit unit, and the third subpixel circuit unit is a minimum length in the second direction between a corresponding fourth signal line in each of the first subpixel circuit unit, the second subpixel circuit unit, and the third subpixel circuit unit and a corresponding fourth signal line in each of another first subpixel circuit unit from the plurality of first subpixel circuit units, another second subpixel circuit unit from the plurality of second subpixel circuit units, and another third subpixel circuit unit from the plurality of third subpixel circuit units adjacent thereto in the second direction.

12. The display device of claim 1, wherein the length in the first direction or the length in the second direction of each of the first subpixel circuit unit, the second subpixel circuit unit, and the third subpixel circuit unit is a minimum length in the first direction or a minimum length in the second direction between a corresponding first storage capacitor electrode in each of the first subpixel circuit unit, the second subpixel circuit unit, and the third subpixel circuit unit and a corresponding second storage capacitor electrode in each of another first subpixel circuit unit from the plurality of first subpixel circuit units, another second subpixel circuit unit from the plurality of second subpixel circuit units, and another third subpixel circuit unit from the plurality of third subpixel circuit units adjacent thereto in the first direction or the second direction, and
wherein the corresponding first storage capacitor electrode and the corresponding second storage capacitor electrode are on a same layer and include a same material.

13. The display device of claim 1, wherein the optical bezel area includes:
an area where the first subpixel circuit unit and a fourth subpixel circuit unit are alternately disposed in the first direction, the fourth subpixel circuit unit and the first subpixel circuit unit symmetrical with respect to a boundary between the first subpixel circuit unit and the fourth subpixel circuit unit; and
an area where the second subpixel circuit unit and a fifth subpixel circuit unit are alternately disposed in the first direction, the second subpixel circuit unit and the fifth subpixel circuit unit symmetrical with respect to a boundary between the second subpixel circuit unit and the fifth subpixel circuit unit.

14. The display device of claim 13, wherein a length in the first direction of each of the first subpixel circuit unit and the fourth subpixel circuit unit is half of a distance in the first direction between third signal lines respectively disposed in the first subpixel circuit unit disposed on a first side of the fourth subpixel circuit unit and another first subpixel circuit unit disposed on a second side of the fourth subpixel circuit unit or between storage capacitor electrodes, and
wherein a length in the first direction of each of the second subpixel circuit unit and the fifth subpixel circuit unit is half of a distance in the first direction between third signal lines respectively disposed in the second subpixel circuit unit disposed on a first side of the fifth subpixel circuit unit and another second subpixel circuit unit disposed on a second side of the fifth subpixel circuit unit or between storage capacitor electrodes.

15. A display panel comprising:
a light transmittable optical area included in a display area of the display panel and configured to display an image;
a normal area included in the display area, the normal area configured to display the image and positioned around the light transmittable optical area;
an optical bezel area between the light transmittable optical area and the normal area in the display area and comprising a first area and a second area that is different from the first area, the optical bezel area configured to display the image; and
a plurality of subpixel circuit units in the optical bezel area, the plurality of subpixel circuit units including a first subpixel circuit unit in the first area and a second subpixel circuit unit in the second area,
wherein one or more dimensions of the first subpixel circuit unit in a plan view of the display panel is different from one or more dimensions of the second subpixel circuit unit in the plan view of the display panel.

16. The display panel of claim 15, wherein the one or more dimensions of the first subpixel circuit comprise a length of the first subpixel circuit unit in a first direction and a length of the first subpixel circuit unit in a second direction, and the one or more dimensions of the second subpixel circuit unit comprise a length of the second subpixel circuit unit in the first direction and a length of the second subpixel circuit unit in the second direction.

17. The display panel of claim 16, wherein the length of the first subpixel circuit unit in the first direction is less than the length of the second subpixel circuit unit in the second direction.

18. The display panel of claim 17, wherein the length of the first subpixel circuit unit in the second direction is greater than the length of the second subpixel circuit unit in the second direction.

19. The display panel of claim 17, wherein the first subpixel circuit unit is included in a plurality of first subpixel circuit units in the first area of the optical bezel area and the second subpixel circuit unit is included in a plurality of second subpixel circuit units in the second area of the optical bezel area,
wherein a density of the plurality of first subpixel circuit units in the first area is less than a density of the plurality of second subpixel circuit units in the second area.

20. The display panel of claim 19, further comprising:
a signal line between the first subpixel circuit unit and another first subpixel unit from the plurality of first subpixel circuit units, the signal line extending at an angle greater than 0° and less than 90° with respect to the first direction.
